(19) United States
(12) Patent Application Publication
(10) Pub. No.: US 2025/0311519 A1
(43) Pub. Date: Oct. 2, 2025

(54) LIGHT-EMITTING ARRAY WITH CONTINUOUS ACTIVE LAYER AND LIGHT OUTCOUPLING STRUCTURES

(71) Applicant: LUMILEDS LLC, San Jose, CA (US)

(72) Inventor: Antonio LOPEZ-JULIA, Vaals (NL)

(73) Assignee: LUMILEDS LLC, San Jose, CA (US)

(21) Appl. No.: 19/236,478

(22) Filed: Jun. 12, 2025

Related U.S. Application Data
(63) Continuation of application No. PCT/US2023/083640, filed on Dec. 12, 2023.
(60) Provisional application No. 63/433,356, filed on Dec. 16, 2022.

(51) Int. Cl. H10H 29/80; B82Y 20/00; H01L 25/075; H10H 20/833; H10H 29/01; H10H 29/37; H10H 29/49; H10H 29/855; H10H 29/856

(52) U.S. Cl. CPC H10H 29/882; B82Y 20/00; H01L 25/0753; H10H 20/833; H10H 29/012; H10H 29/0363; H10H 29/0364; H10H 29/37; H10H 29/49; H10H 29/8552; H10H 29/856

(57) ABSTRACT

A light-emitting array includes a semiconductor LED structure, multiple outcoupling structures, multiple independent first electrical contacts, and second electrical contact(s). The LED structure extends contiguously over the array. The second electrical contacts are in electrical contact with the second semiconductor layer. Each outcoupling structure is a protruding portion of the second semiconductor layer. Each first electrical contact includes a circumscribed electrode layer opposite a corresponding outcoupling structure. Each outcoupling structure and corresponding first electrical contact define a corresponding discrete, circumscribed pixel region within the contiguous area of the array, each pixel region separate from the others. Some light emitted in the pixel region is collected or redirected by the outcoupling structure to exit the outcoupling structure and propagate away from the array.

### BENEFIT CLAIM

This application is a continuation of international App. No. PCT/US2023/083640 entitled “Light-emitting array with continuous active layer and light outcoupling structures” filed 12 Dec. 2023 in the name of Antonio Lopez-Julia, which claims priority of U.S. provisional App. No. 63/433,356 entitled “Light-emitting array with continuous active layer and light outcoupling structures” filed 16 Dec. 2022 in the name of Antonio Lopez-Julia; both of said applications are incorporated herein by reference in their entireties.

### FIELD OF THE INVENTION

The invention relates generally to light emitting diodes and to phosphor-converted light emitting diodes.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer.

Phosphor-converted LEDs may be designed so that all of the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED.

Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Multiple LEDs or pcLEDs can be formed together on a single substrate to form an array. Such arrays can be employed to form active illuminated displays, such as those employed in, e.g., smartphones and smart watches, computer or video displays, augmented- or virtual-reality displays, or signage, or to form adaptive illumination sources, such as those employed in, e.g., automotive headlights, street lighting, camera flash sources, or flashlights (i.e., torches). An array having one or several or many individual devices per millimeter (e.g., device pitch or spacing of about a millimeter, a few hundred microns, or less than 100 microns, and separation between adjacent devices less than 100 microns or only a few tens of microns or less) typically is referred to as a miniLED array or a microLED array (alternatively, a μLED array). Such mini- or microLED arrays can in many instances also include phosphor converters as described above; such arrays can be referred to as pc-miniLED or pc-microLED arrays.

### SUMMARY

An inventive semiconductor light-emitting array includes a semiconductor light-emitting diode structure, multiple outcoupling structures, multiple independent first electrical contacts, and second electrical contact(s). The diode structure includes first and second doped semiconductor layers and a junction or active layer between them. The diode structure emits light at a nominal emission vacuum wavelength λ₀ resulting from carrier recombination at the junction or active layer. The first and second semiconductor layers and the junction or active layer are coextensive over a contiguous area of the array. The second electrical contacts are in electrical contact with the second semiconductor layer. Each of the multiple outcoupling structure comprises protruding portions of the second semiconductor layer that protrude away from a first surface thereof opposite the first semiconductor layer. The outcoupling structures collect or redirect at least some of the light emitted by the active layer to exit the outcoupling structure and propagate away from the array. A corresponding circumscribed electrically conductive first electrode layer is positioned on a first surface of the first semiconductor layer opposite the second semiconductor layer, and opposite each outcoupling structure. The first electrode layer is in electrical contact with the first semiconductor layer at the first surface thereof and forms at least a portion of a corresponding one of multiple, independent first electrical contacts. Each outcoupling structure and the corresponding first electrical contact define a corresponding discrete, circumscribed pixel region within the contiguous area of the array that is separated from other circumscribed pixel regions of the array.

Objects and advantages pertaining to LEDs, pcLEDs, miniLED arrays, pc-miniLED arrays, microLED arrays, and pc-microLED arrays may become apparent upon referring to the examples illustrated in the drawings and disclosed in the following written description or appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 shows a schematic cross-sectional view of an example pcLED.

FIGS. 2A and 2B show, respectively, cross-sectional and top schematic views of an example array of pcLEDs.

FIG. 3A shows a schematic cross-sectional view of an example array of pcLEDs arranged with respect to waveguides and a projection lens. FIG. 3B shows an arrangement similar to that of FIG. 3A, but without the waveguides.

FIG. 4A shows a top schematic view of an example miniLED or microLED array and an enlarged section of 3×3 LEDs of the array. FIG. 4B is a side cross-sectional schematic diagram of an example of a close-packed array of multi-colored phosphor-converted LEDS on a monolithic die and substrate.

FIG. 5A is a schematic top view of a portion of an example LED display in which each display pixel is a red, green, or blue phosphor-converted LED pixel. FIG. 5B is a schematic top view of a portion of an example LED display in which each display pixel includes multiple phosphor-converted LED pixels (red, green, and blue) integrated onto a single die that is bonded to a control circuit backplane.

FIG. 6A shows a schematic top view an example electronics board on which an array of pcLEDs may be mounted, and FIG. 6B similarly shows an example array of pcLEDs mounted on the electronic board of FIG. 6A.

FIG. 7A schematically illustrates an example camera flash system. FIG. 7B schematically illustrates an example display system. FIG. 7C shows a block diagram of an example visualization system.

FIG. 8 is a schematic cross-sectional view of a light-emitting array with etched active layers.

FIGS. 9-21 are schematic cross-sectional views of various examples of inventive light-emitting arrays each having a contiguous active layer.

FIGS. 22A-22E illustrate schematically various examples of nanostructured optical elements.

The examples depicted are shown only schematically; all features may not be shown in full detail or in proper proportion; for clarity certain features or structures may be exaggerated or diminished relative to others or omitted entirely; the drawings should not be regarded as being to scale unless explicitly indicated as being to scale. For example, individual LEDs may be exaggerated in their vertical dimensions or layer thicknesses relative to their lateral extent or relative to substrate or phosphor thicknesses. The examples shown should not be construed as limiting the scope of the present disclosure or appended claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the inventive subject matter. The detailed description illustrates by way of example, not by way of limitation, the principles of the inventive subject matter. For purposes of simplicity and clarity, detailed descriptions of well-known devices, circuits, and methods may be omitted so as not to obscure the description of the inventive subject matter with unnecessary detail.

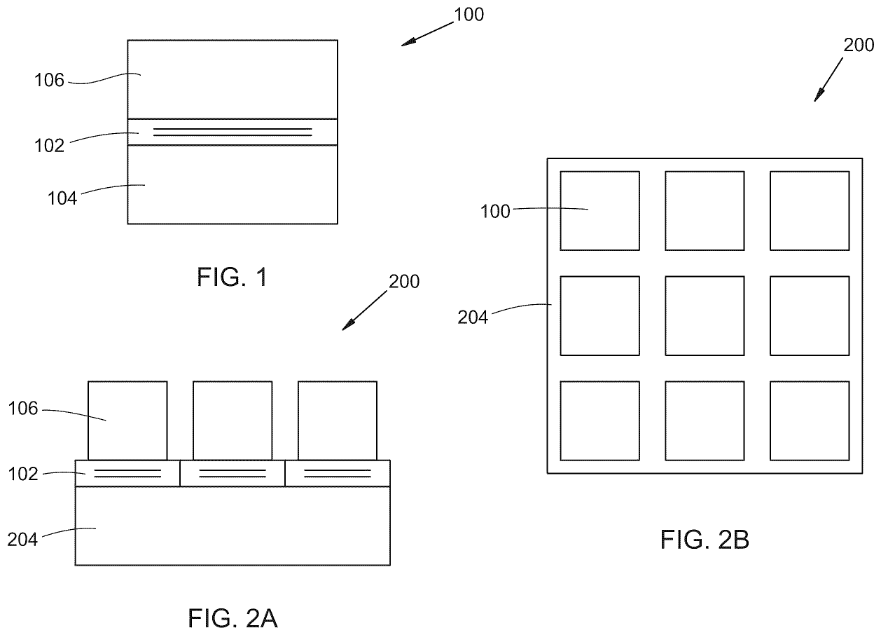

FIG. 1 shows an example of an individual pcLED 100 comprising a semiconductor diode structure 102 disposed on a substrate 104, together considered herein an “LED” or “semiconductor LED”, and a wavelength converting structure (e.g., phosphor layer) 106 disposed on the semiconductor LED. Semiconductor diode structure 102 typically comprises an active region disposed between n-type and p-type layers. Application of a suitable forward bias across the diode structure 102 results in emission of light from the active region. The wavelength of the emitted light is determined by the composition and structure of the active region.

The LED may be, for example, a III-Nitride LED that emits blue, violet, or ultraviolet light. LEDs formed from any other suitable material system and that emit any other suitable wavelength of light may also be used. Other suitable material systems may include, for example, III-Phosphide materials, III-Arsenide materials, other binary, ternary, or quaternary alloys of gallium, aluminum, indium, nitrogen, phosphorus, or arsenic, or II-VI materials.

Any suitable phosphor materials may be used for or incorporated into the wavelength converting structure 106, depending on the desired optical output from the pcLED.

FIGS. 2A-2B show, respectively, cross-sectional and top views of an array 200 of pcLEDs 100, each including a phosphor pixel 106, disposed on a substrate 204. Such an array can include any suitable number of pcLEDs arranged in any suitable manner. In the illustrated example the array is depicted as formed monolithically on a shared substrate, but alternatively an array of pcLEDs can be formed from separate individual pcLEDs (e.g., singulated devices that are assembled onto an array substrate). Individual phosphor pixels 106 are shown in the illustrated example, but alternatively a contiguous layer of phosphor material can be disposed across multiple LEDs 102. In some instances the array 200 can include light barriers (e.g., reflective, scattering, and/or absorbing) between adjacent LEDs 102, phosphor pixels 106, or both. Substrate 204 may optionally include electrical traces or interconnects, or CMOS or other circuitry for driving the LED, and may be formed from any suitable materials.

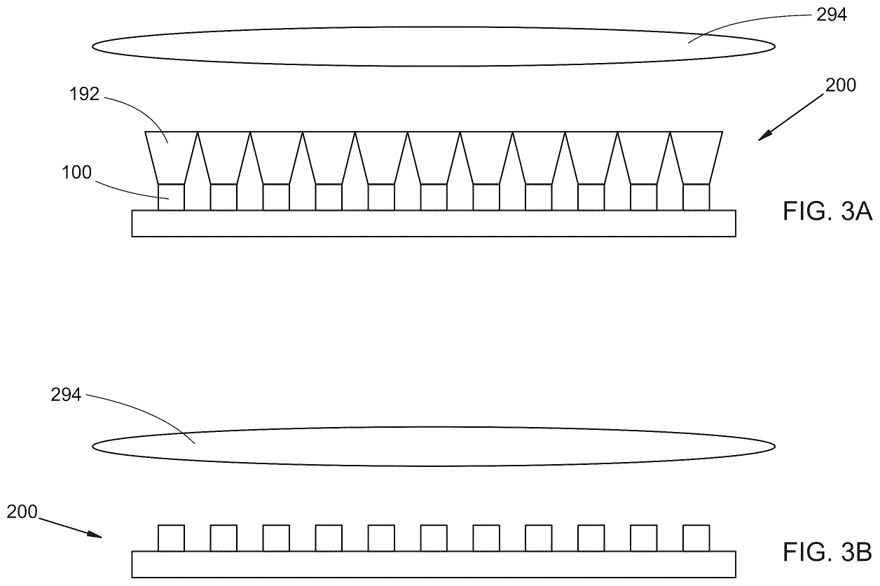

Individual pcLEDs 100 may optionally incorporate or be arranged in combination with a lens or other optical element located adjacent to or disposed on the phosphor layer. Such an optical element, not shown in the figures, may be referred to as a “primary optical element”. In addition, as shown in FIGS. 3A and 3B, a pcLED array 200 (for example, mounted on an electronics board) may be arranged in combination with secondary optical elements such as waveguides, lenses, or both for use in an intended application. In FIG. 3A, light emitted by each pcLED 100 of the array 200 is collected by a corresponding waveguide 192 and directed to a projection lens 294. Projection lens 294 may be a Fresnel lens, for example. This arrangement may be suitable for use, for example, in automobile headlights or other adaptive illumination sources. Other primary or secondary optical elements of any suitable type or arrangement can be included for each pixel, as needed or desired. In FIG. 3B, light emitted by pcLEDs of the array 200 is collected directly by projection lens 294 without use of intervening waveguides. This arrangement may particularly be suitable when pcLEDs can be spaced sufficiently close to each other, and may also be used in automobile headlights as well as in camera flash applications or other illumination sources. A miniLED or microLED display application may use similar optical arrangements to those depicted in FIGS. 3A and 3B, for example. Generally, any suitable arrangement of optical elements (primary, secondary, or both) can be used in combination with the pcLEDs described herein, depending on the desired application.

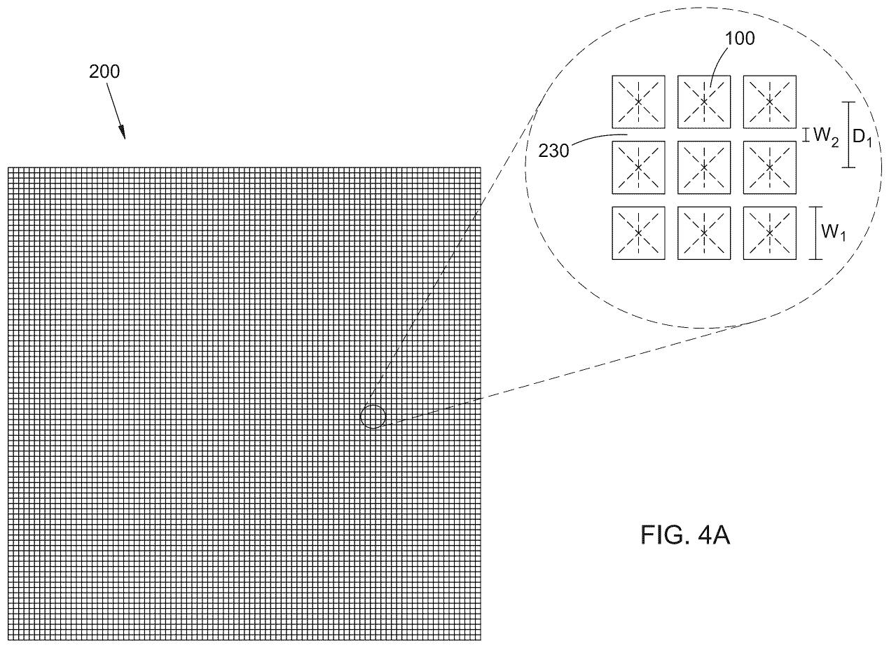

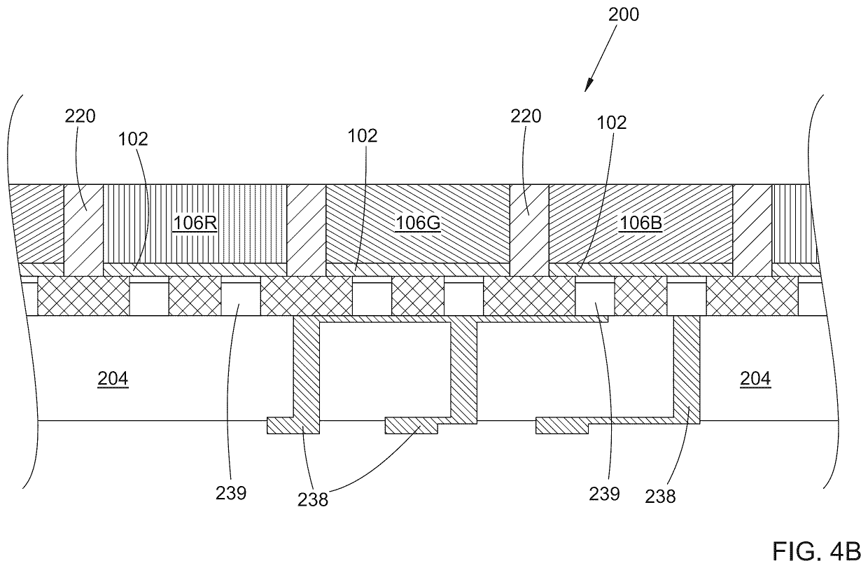

Although FIGS. 2A and 2B show a 3×3 array of nine pcLEDs, such arrays may include for example on the order of 101, 102, 103, 104, or more LEDs, e.g., as illustrated schematically in FIG. 4A. Individual LEDs 100 (i.e., pixels) may have widths w₁ (e.g., side lengths) in the plane of the array 200, for example, less than or equal to 1 millimeter (mm), less than or equal to 500 microns, less than or equal to 100 microns, or less than or equal to 50 microns. LEDs 100 in the array 200 may be spaced apart from each other by streets, lanes, or trenches 230 having a width w₂ in the plane of the array 200 of, for example, hundreds of microns, less than or equal to 100 microns, less than or equal to 50 microns, less than or equal to 20 microns, less than or equal to 10 microns, or less than or equal to 5 microns. The pixel pitch or spacing D₁ is the sum of w₁ and w₂. Although the illustrated examples show rectangular pixels arranged in a symmetric matrix, the pixels and the array may have any suitable shape or arrangement, whether symmetric or asymmetric. Multiple separate arrays of LEDs can be combined in any suitable arrangement in any applicable format to form a larger combined array or display.

LEDs having dimensions w₁ in the plane of the array (e.g., side lengths) of less than or equal to about 0.10 millimeters microns are typically referred to as microLEDs, and an array of such microLEDs may be referred to as a microLED array. LEDs having dimensions w₁ in the plane of the array (e.g., side lengths) of between about 0.10 millimeters and about 1.0 millimeters are typically referred to as miniLEDs, and an array of such miniLEDs may be referred to as a miniLED array.

FIG. 4B is a schematic cross-sectional view of a close packed array 200 of multi-colored, phosphor converted LEDs 100 on a monolithic die and substrate 204. The side view shows GaN LEDs 102 attached to the substrate 204 through metal interconnects 239 (e.g., gold-gold interconnects or solder attached to copper micropillars) and metal interconnects 238. Phosphor pixels 106 are positioned on or over corresponding GaN LED pixels 102. The semiconductor LED pixels 102 or phosphor pixels 106 (often both) can be coated on their sides with a reflective mirror or diffusive scattering layer to form an optical isolation barrier 220. In this example each phosphor pixel 106 is one of three different colors, e.g., red phosphor pixels 106R, green phosphor pixels 106G, and blue phosphor pixels 106B (still referred to generally or collectively as phosphor pixels 106). Such an arrangement can enable use of the LED array 200 as a color display.

The individual LEDs (pixels) in an LED array may be individually addressable, may be addressable as part of a group or subset of the pixels in the array, or may not be addressable. Thus, light emitting pixel arrays are useful for any application requiring or benefiting from fine-grained intensity, spatial, and temporal control of light distribution. These applications may include, but are not limited to, precise special patterning of emitted light from pixel blocks or individual pixels, in some instances including the formation of images as a display device. Depending on the application, emitted light may be spectrally distinct, adaptive over time, and/or environmentally responsive. The light emitting pixel arrays may provide preprogrammed light distribution in various intensity, spatial, or temporal patterns. The emitted light may be based at least in part on received sensor data and may be used for optical wireless communications. Associated electronics and optics may be distinct at a pixel, pixel block, or device level.

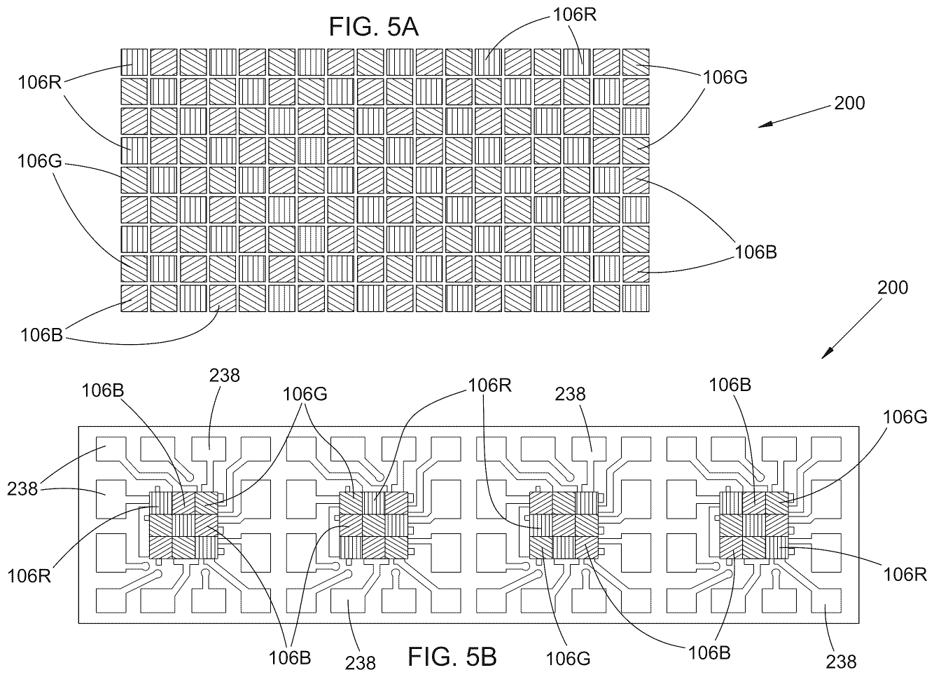

FIGS. 5A and 5B are examples of LED arrays 200 employed in display applications, wherein an LED display includes a multitude of display pixels. In some examples (e.g., as in FIG. 5A), each display pixel comprises a single semiconductor LED pixel 102 and a corresponding phosphor pixel 106R, 106G, or 106B of a single color (red, green, or blue). Each display pixel only provides one of the three colors. In some examples (e.g., as in FIG. 5B), each display pixel includes multiple semiconductor LED pixels 102 and multiple corresponding phosphor pixels 106 of multiple colors. In the example shown each display pixel includes a 3×3 array of semiconductor pixels 102; three of those LED pixels have red phosphor pixels 106R, three have green phosphor pixels 106G, and three have blue phosphor pixels 106B. Each display pixel can therefore produce any desired color combination. In the example shown the spatial arrangement of the different colored phosphor pixels 106 differs among the display pixels; in some examples (not shown) each display pixel can have the same arrangement of the different colored phosphor pixels 106.

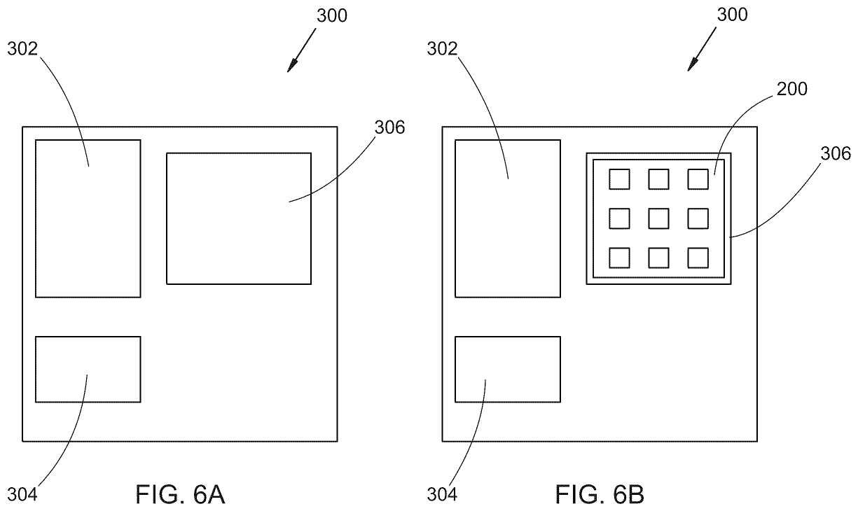

As shown in FIGS. 6A and 6B, a pcLED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, pcLED array 200 may be mounted on a separate board (not shown) from the power and control module and the sensor module.

An array of independently operable LEDs or pcLEDs may be used in combination with a lens, lens system, or other optic or optical system (e.g., as described above) to provide illumination that is adaptable for a particular purpose. For example, in operation such an adaptive lighting system may provide illumination that varies by color and/or intensity across an illuminated scene or object and/or is aimed in a desired direction. Beam focus or steering of light emitted by the LED or pcLED array can be performed electronically by activating LEDs or pcLEDs in groups of varying size or in sequence, to permit dynamic adjustment of the beam shape and/or direction without moving optics or changing the focus of the lens in the lighting apparatus. A controller can be configured to receive data indicating locations and color characteristics of objects or persons in a scene and based on that information control LEDs or pcLEDs in an array to provide illumination adapted to the scene. Such data can be provided for example by an image sensor, or optical (e.g., laser scanning) or non-optical (e.g., millimeter radar) sensors. Such adaptive illumination is increasingly important for automotive (e.g., adaptive headlights), mobile device camera (e.g., adaptive flash), AR, VR, and MR applications such as those described below.

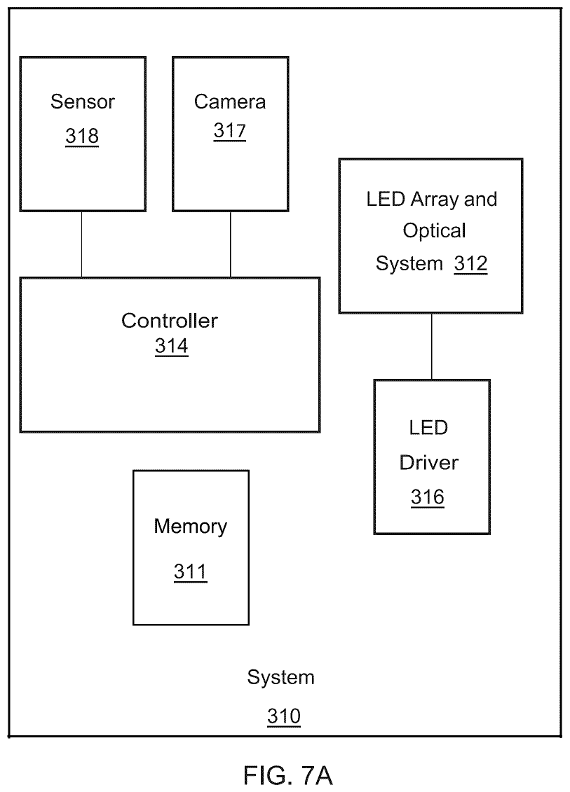

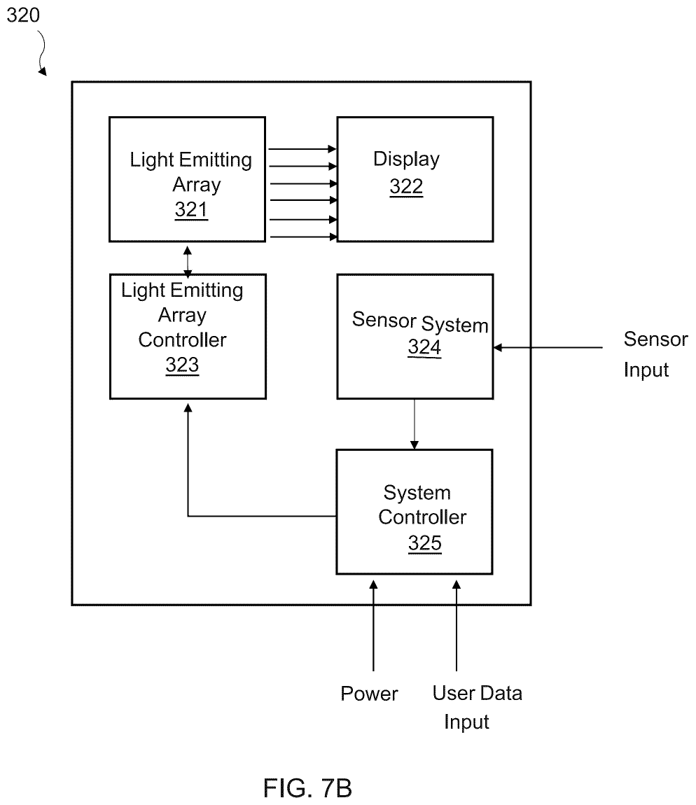

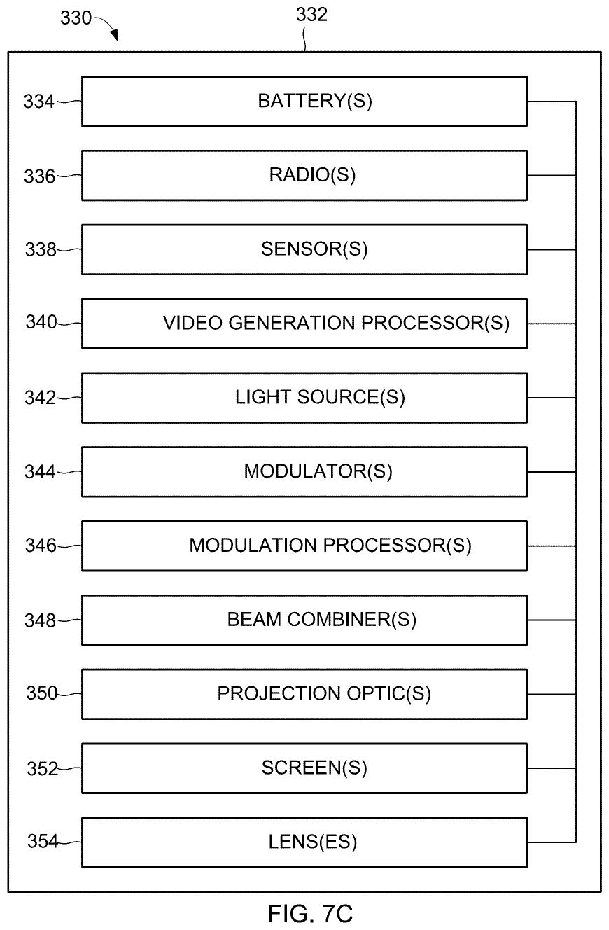

FIG. 7A schematically illustrates an example camera flash system 310 comprising an LED or pcLED array and an optical (e.g., lens) system 312, which may be or comprise an adaptive lighting system as described above in which LEDs or pcLEDs in the array may be individually operable or operable as groups. In operation of the camera flash system, illumination from some or all of the LEDs or pcLEDs in array and optical system 312 may be adjusted—deactivated, operated at full intensity, or operated at an intermediate intensity. The array may be a monolithic array, or comprise one or more monolithic arrays, as described above. The array may be a microLED array, as described above.

Flash system 310 also comprises an LED driver 316 that is controlled by a controller 314, such as a microprocessor. Controller 314 may also be coupled to a camera 317 and to sensors 318 and operate in accordance with instructions and profiles stored in memory 311. Camera 317 and LED or pcLED array and lens system 312 may be controlled by controller 314 to, for example, match the illumination provided by system 312 (i.e., the field of view of the illumination system) to the field of view of camera 317, or to otherwise adapt the illumination provided by system 312 to the scene viewed by the camera as described above. Sensors 318 may include, for example, positional sensors (e.g., a gyroscope and/or accelerometer) and/or other sensors that may be used to determine the position and orientation of system 310.

FIG. 7B schematically illustrates an example display system 320 that includes an array 321 of LEDs or pcLEDs that are individually operable or operable in groups, a display 322, a light emitting array controller 323, a sensor system 324, and a system controller 325. Array 321 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Similarly, to provide redundancy in the event of a defective LED or pcLED, a group of six individually operable adjacent LEDs or pcLEDs comprising two red emitters, two blue emitters, and two green emitters may correspond to a single color-tunable pixel in the display Array 321 can be used to project light in graphical or object patterns that can for example support AR/VR/MR systems. In some cases the individual emitters can be referred to as pixels even if several are operated together to act as a single pixel of a display.

Sensor input is provided to the sensor system 324, while power and user data input is provided to the system controller 325. In some embodiments modules included in system 320 can be compactly arranged in a single structure, or one or more elements can be separately mounted and connected via wireless or wired communication. For example, array 321, display 322, and sensor system 324 can be mounted on a headset or glasses, with the light emitting array controller and/or system controller 325 separately mounted.

System 320 can incorporate a wide range of optics (not shown) to couple light emitted by array 321 into display 322. Any suitable optics may be used for this purpose.

Sensor system 324 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input through the sensor system can include detected touch or taps, gestural input, or control based on headset or display position.

In response to data from sensor system 324, system controller 325 can send images or instructions to the light emitting array controller 323. Changes or modification to the images or instructions can also be made by user data input, or automated data input as needed. User data input can include but is not limited to that provided by audio instructions, haptic feedback, eye or pupil positioning, or connected keyboard, mouse, or game controller.

As noted above, AR, VR, and MR systems may be more generally referred to as examples of visualization systems. In a virtual reality system, a display can present to a user a view of scene, such as a three-dimensional scene. The user can move within the scene, such as by repositioning the user's head or by walking. The virtual reality system can detect the user's movement and alter the view of the scene to account for the movement. For example, as a user rotates the user's head, the system can present views of the scene that vary in view directions to match the user's gaze. In this manner, the virtual reality system can simulate a user's presence in the three-dimensional scene. Further, a virtual reality system can receive tactile sensory input, such as from wearable position sensors, and can optionally provide tactile feedback to the user.

In an augmented reality system, the display can incorporate elements from the user's surroundings into the view of the scene. For example, the augmented reality system can add textual captions and/or visual elements to a view of the user's surroundings. For example, a retailer can use an augmented reality system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the augmented reality system can position a virtual chair in a room. The user can stand in the room on a front side of the virtual chair location to view the front side of the chair. The user can move in the room to an area behind the virtual chair location to view a back side of the chair. In this manner, the augmented reality system can add elements to a dynamic view of the user's surroundings.

FIG. 7C shows a generalized block diagram of an example visualization system 330. The visualization system 330 can include a wearable housing 332, such as a headset or goggles. The housing 332 can mechanically support and house the elements detailed below. In some examples, one or more of the elements detailed below can be included in one or more additional housings that can be separate from the wearable housing 332 and couplable to the wearable housing 332 wirelessly and/or via a wired connection. For example, a separate housing can reduce the weight of wearable goggles, such as by including batteries, radios, and other elements. The housing 332 can include one or more batteries 334, which can electrically power any or all of the elements detailed below. The housing 332 can include circuitry that can electrically couple to an external power supply, such as a wall outlet, to recharge the batteries 334. The housing 332 can include one or more radios 336 to communicate wirelessly with a server or network via a suitable protocol, such as WiFi.

The visualization system 330 can include one or more sensors 338, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 338 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 338 can capture a real-time video image of the surroundings proximate a user.

The visualization system 330 can include one or more video generation processors 340. The one or more video generation processors 340 can receive, from a server and/or a storage medium, scene data that represents a three-dimensional scene, such as a set of position coordinates for objects in the scene or a depth map of the scene. The one or more video generation processors 340 can receive one or more sensor signals from the one or more sensors 338. In response to the scene data, which represents the surroundings, and at least one sensor signal, which represents the location and/or orientation of the user with respect to the surroundings, the one or more video generation processors 340 can generate at least one video signal that corresponds to a view of the scene. In some examples, the one or more video generation processors 340 can generate two video signals, one for each eye of the user, that represent a view of the scene from a point of view of the left eye and the right eye of the user, respectively. In some examples, the one or more video generation processors 340 can generate more than two video signals and combine the video signals to provide one video signal for both eyes, two video signals for the two eyes, or other combinations.

The visualization system 330 can include one or more light sources 342 that can provide light for a display of the visualization system 330. Suitable light sources 342 can include any of the LEDs, pcLEDs, LED arrays, and pcLED arrays discussed above, for example those discussed above with respect to display system 320.

The visualization system 330 can include one or more modulators 344. The modulators 344 can be implemented in one of at least two configurations.

In a first configuration, the modulators 344 can include circuitry that can modulate the light sources 342 directly. For example, the light sources 342 can include an array of light-emitting diodes, and the modulators 344 can directly modulate the electrical power, electrical voltage, and/or electrical current directed to each light-emitting diode in the array to form modulated light. The modulation can be performed in an analog manner and/or a digital manner. In some examples, the light sources 342 can include an array of red light-emitting diodes, an array of green light-emitting diodes, and an array of blue light-emitting diodes, and the modulators 344 can directly modulate the red light-emitting diodes, the green light-emitting diodes, and the blue light-emitting diodes to form the modulated light to produce a specified image.

In a second configuration, the modulators 344 can include a modulation panel, such as a liquid crystal panel. The light sources 342 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 344 can include multiple modulation panels that can modulate different colors of light. For example, the modulators 344 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 344 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 330 can include one or more modulation processors 346, which can receive a video signal, such as from the one or more video generation processors 340, and, in response, can produce an electrical modulation signal. For configurations in which the modulators 344 directly modulate the light sources 342, the electrical modulation signal can drive the light sources 344. For configurations in which the modulators 344 include a modulation panel, the electrical modulation signal can drive the modulation panel.

The visualization system 330 can include one or more beam combiners 348 (also known as beam splitters 348), which can combine light beams of different colors to form a single multi-color beam. For configurations in which the light sources 342 can include multiple light-emitting diodes of different colors, the visualization system 330 can include one or more wavelength-sensitive (e.g., dichroic) beam splitters 348 that can combine the light of different colors to form a single multi-color beam.

The visualization system 330 can direct the modulated light toward the eyes of the viewer in one of at least two configurations. In a first configuration, the visualization system 330 can function as a projector, and can include suitable projection optics 350 that can project the modulated light onto one or more screens 352. The screens 352 can be located a suitable distance from an eye of the user. The visualization system 330 can optionally include one or more lenses 354 that can locate a virtual image of a screen 352 at a suitable distance from the eye, such as a close-focus distance, such as 500 mm, 750 mm, or another suitable distance. In some examples, the visualization system 330 can include a single screen 352, such that the modulated light can be directed toward both eyes of the user. In some examples, the visualization system 330 can include two screens 352, such that the modulated light from each screen 352 can be directed toward a respective eye of the user. In some examples, the visualization system 330 can include more than two screens 352. In a second configuration, the visualization system 330 can direct the modulated light directly into one or both eyes of a viewer. For example, the projection optics 350 can form an image on a retina of an eye of the user, or an image on each retina of the two eyes of the user.

For some configurations of augmented reality systems, the visualization system 330 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

For purposes of the present disclosure and appended claims, any arrangement of a layer, surface, substrate, diode structure, or other structure “on,” “over,” or “against” another such structure shall encompass arrangements with direct contact between the two structures as well as arrangements including some intervening structure between them. Conversely, any arrangement of a layer, surface, substrate, diode structure, or other structure “directly on,” “directly over,” or “directly against” another such structure shall encompass only arrangements with direct contact between the two structures. For purposes of the present disclosure and appended claims, a layer, structure, or material described as “transparent” and “substantially transparent” shall exhibit, at the nominal emission vacuum wavelength 2, a level of optical transmission that is sufficiently high, or a level of optical loss (due to absorption, scattering, or other loss mechanism) that is sufficiently low, that the light-emitting device can function within operationally acceptable parameters (e.g., output power or luminance, conversion or extraction efficiency, or other figures-of-merit including any described herein).

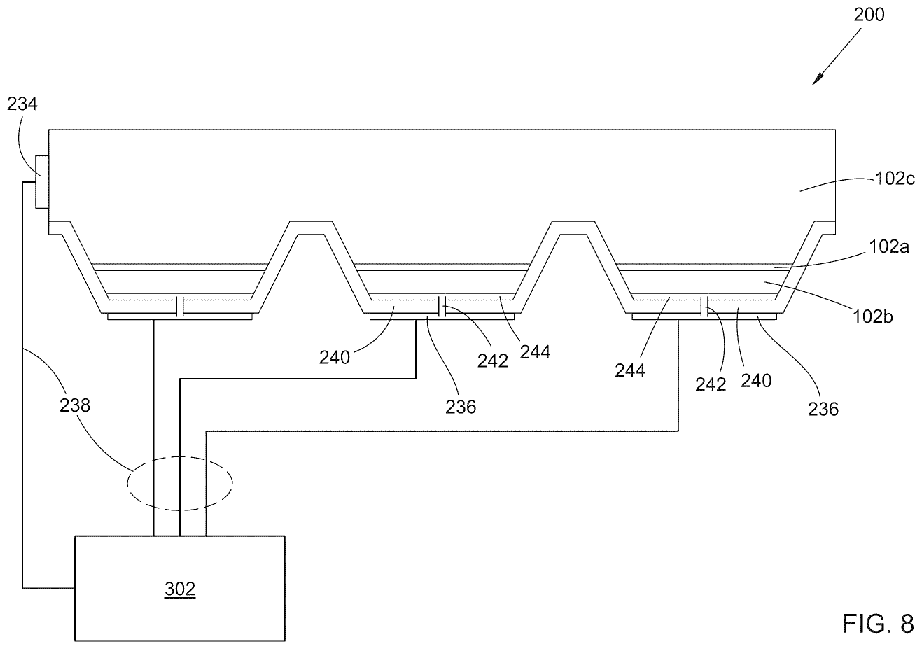

In many previous examples (including some of those shown above), multiple individual LED devices 102 are formed monolithically on a common layered semiconductor structure by etching trenches to form mesa-like structures separated by the trenches (e.g., as in FIG. 8). Each mesa forms a separate LED device or pixel 102, with the trenches extending through at least one (and sometimes both) of the doped semiconductor layers and the junction or active layer between them. In the example of FIG. 8, trenches extend entirely through the p-type semiconductor layer 102b and the active layer 102a, but only partly through the n-type semiconductor layer 102c. In this common arrangement the partly etched layer 102c holds the multiple LED devices 102 together in a monolithically integrated array 200. Drive current can be directed through each mesa independently of the others via traces 238, contacts 234 and 236, vias 242, and transparent electrodes 244 in the example of FIG. 8 (in which an electrically insulating dielectric layer 240 separates the contact 236 from the electrode layer 244). The surrounding trench walls laterally confine the drive current delivered to each mesa, so that the corresponding pixel 102 is independently addressable. However, as pixel sizes or spacings get smaller, a number of factors limit light output from each pixel, contrast between adjacent pixels 102, or both.

One such factor is decreased internal quantum efficiency of light emission due to non-radiative carrier recombination at defect sites at the etched sidewalls. Such defects are an unavoidable byproduct of the etch process, and their relative importance increases with decreasing pixel size; as transverse pixel size decreases, sidewall perimeter decreases linearly while emission area decreases quadratically. For pixel sizes greater than, e.g., 50 or 100 μm across, the effect of recombination at sidewall defects is relatively unimportant, or at least tolerable. As pixel size shrinks to 20 μm, 10 μm, or even less, a greater fraction of overall carrier recombination is non-radiative recombination at the sidewalls, and internal quantum efficiency suffers accordingly.

Another factor is increasingly difficult light extraction as pixel size decreases. A common method for increasing light extraction from a semiconductor LED is to provide texturing of the light-exit surface of the device. Such texturing can be formed by growing the semiconductor layers on a substrate having corrugations or other similar surface structural features, or by depositing a layer of scattering particles on the light-exit surface. However, the resulting structures typically have feature sizes of at least several microns or several tens of microns, and so cannot be readily implemented on an LED pixel that is too small, e.g., less than 5 or 10 μm across. Even if structurally realizable at such small pixel sizes, such light-extraction surface features would severely degrade contrast between adjacent pixels. The common arrangement of FIG. 8, with inter-pixel trenches extending only partly through one of the semiconductor layers, also permits light emitted from one pixel 102 to propagate into end exit the array from a different pixel 102, as indicated by some of the heavy arrows in FIG. 8.

Accordingly, it would be desirable to provide a light-emitting device that exhibits adequate, desirable, or improved levels of internal quantum efficiency or light extraction. It would be desirable to provide a monolithic array of LED pixels, including arrays having pixels sizes less than 20 μm, 10 μm, or even 5 μm, while maintaining such levels of internal quantum efficiency or light extraction, or adequate, desirable, or improved levels of pixel contrast.

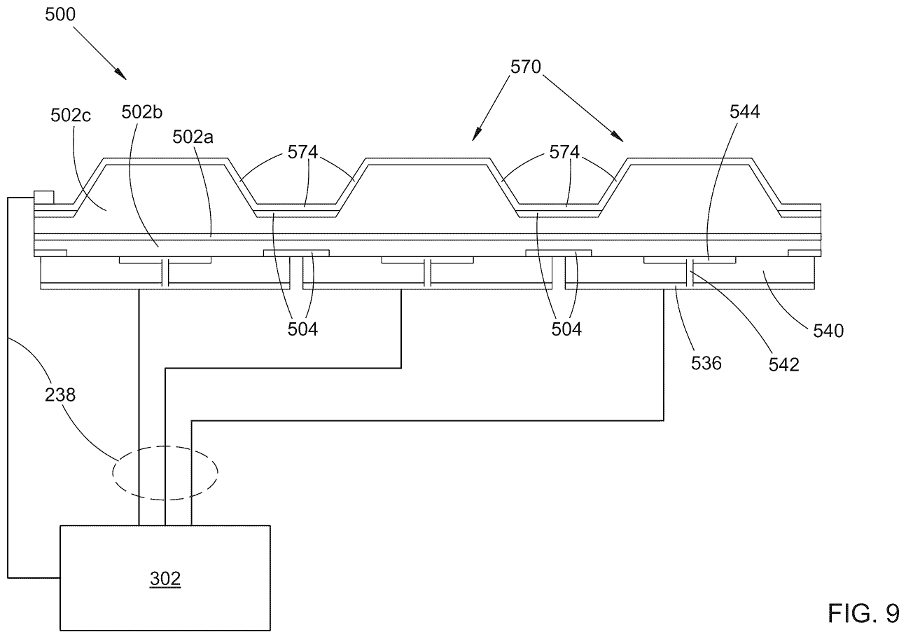

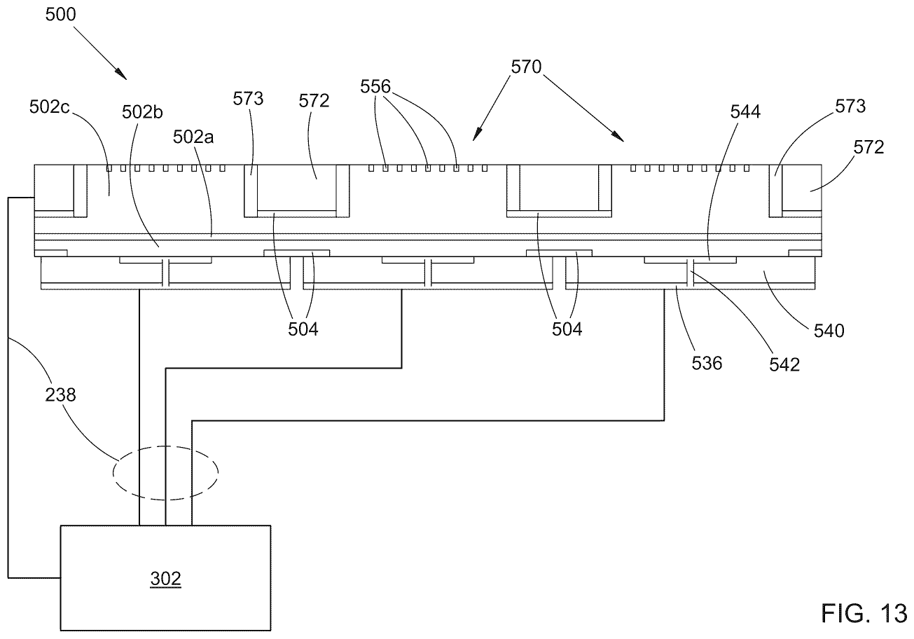

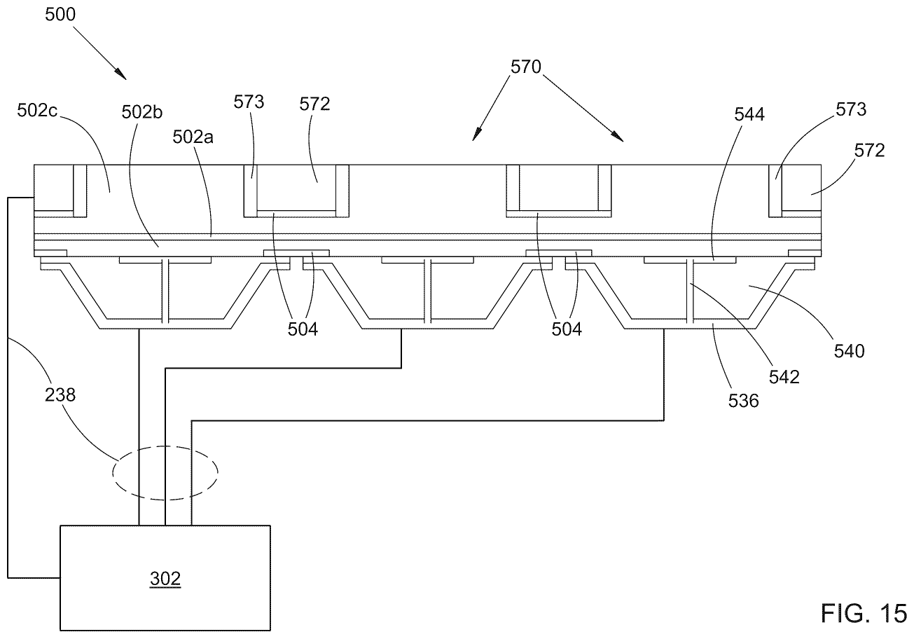

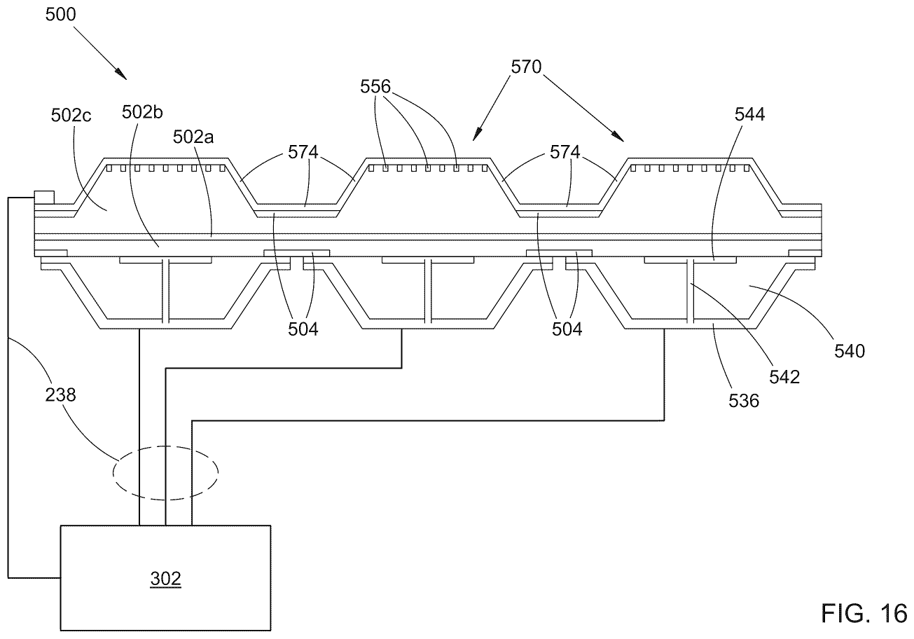

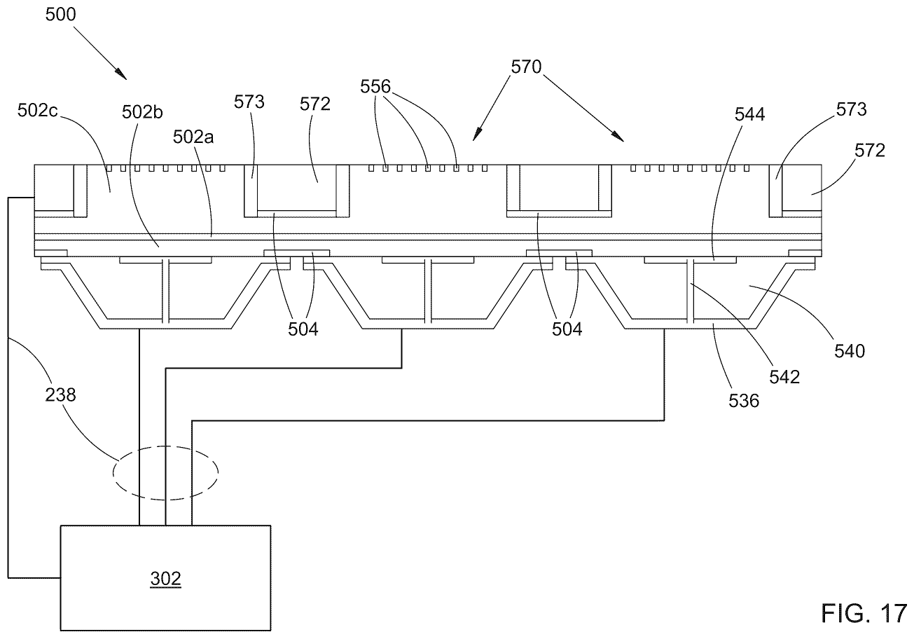

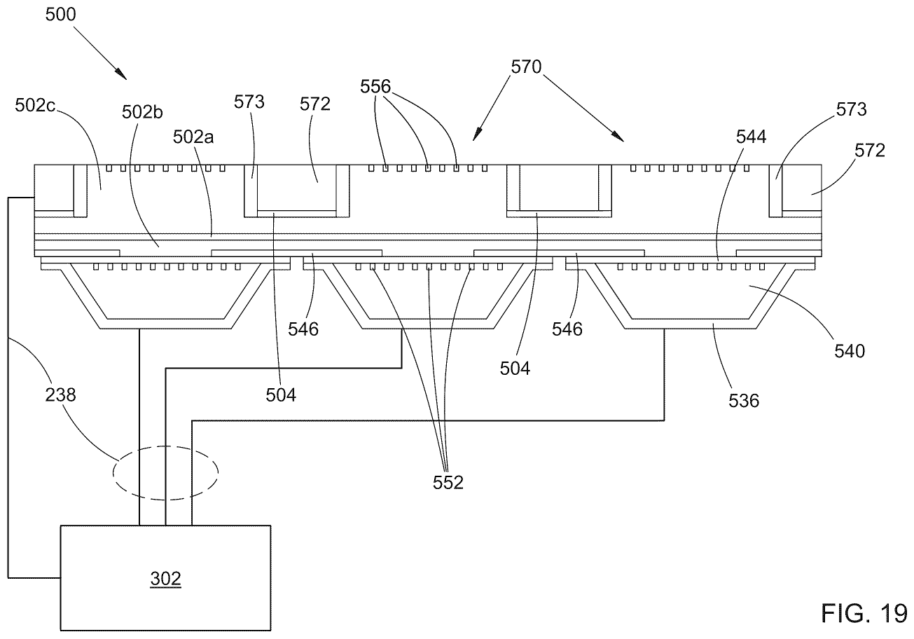

Various examples of inventive light-emitting arrays 500 are illustrated schematically (in cross-section) in FIGS. 9 through 21. The corresponding plan views are not shown; the pixels of the array 500 can be arranged in any suitable way; a rectangular array is commonly employed. An inventive semiconductor light-emitting array 500 comprises a light-emitting diode structure 502a/502b/502c, multiple outcoupling structures 570, multiple, independent first electrical contacts, and one or more second electrical contacts. First and second doped semiconductor layers 502b and 502c, respectively, are arranged for emitting light at a nominal emission vacuum wavelength λ₀. That emission results from carrier recombination at a junction or active layer 502a between the semiconductor layers 502b/502c. The semiconductor layers 502b/502c and the junction or active layer 502a are coextensive over a contiguous area of the array 500. In other words, for most pixels of the array 500 there are no etched edges of the junction or active layer 502a where defect sites can induce excessive non-radiative recombination.

In some examples the first and second semiconductor layers 502b/502c and the junction or active layer 502a can form a semiconductor light-emitting diode (LED) structure. In some examples the diode structure (i.e., one or more of layers 502a/502b/502c) can include one or more doped or undoped III-V, II-VI, or Group IV semiconductor materials or alloys or mixtures thereof. In some examples the layer 502b can be a p-doped semiconductor layer and the layer 502c can be an n-doped semiconductor layer. In some examples the junction or active layer 502a can include one or more p-n junctions, one or more quantum wells, one or more multi-quantum wells, or one or more quantum dots. In some examples the nominal emission vacuum wavelength λ₀ can be greater than 0.20 μm, greater than 0.4 μm, greater than 0.8 μm, less than 10. μm, less than 2.5 μm, or less than 1.0 μm. In some examples the total nonzero thickness of the semiconductor layers 502b/502c and the junction or active layer 502a can be less than 10. μm, less than 5 μm, less than 3 μm, less than 2.0 μm, less than 1.5 μm, or less than 1.0 μm. In some examples the nonzero thickness of the first semiconductor layer 502b can be less than about 1.0 μm, less than about 0.8 μm, less than about 0.5 μm, or less than about 0.3 μm. In some examples the nonzero thickness of the second semiconductor layer 502c in regions between the outcoupling structure 570 can be less than about 1.0 μm, less than about 0.8 μm, less than about 0.5 μm, or less than about 0.3 μm.

Each of the multiple outcoupling structures 570 comprises a protruding portion of the second semiconductor layer 502c. The outcoupling structures 570 protrude away from the semiconductor layer 502c from the surface opposite the first semiconductor layer 502b. Each outcoupling structure is structurally arranged so as to collect or redirect at least some of the light emitted by the active layer 502a to exit the outcoupling structure 570 and propagate away from the array 500.

On a first surface of the first semiconductor layer 502b opposite the second semiconductor layer 502c, and opposite each outcoupling structure 570, is a corresponding circumscribed electrically conductive first electrode layer 544. The electrode layer 544 is in electrical contact with the first semiconductor layer 502b at its first surface, and forms at least a portion of a corresponding one of multiple, independent first electrical contacts. Each outcoupling structure 570 and the corresponding first electrical contact together define a corresponding discrete, circumscribed pixel region within the contiguous area of the array 500. Each pixel region is separated from other circumscribed pixel regions of the array 500. Localized flow of charge carriers constrained by the circumscribed electrode layer 544 results in localized emission from the active layer 502a; the outcoupling structure 570 is positioned to collect or redirect at least a portion of that localized emission to exit the outcoupling structure 570 and propagate away from the array 500. The net effect is that the discrete pixel regions can act as independently operable light-emitting elements of the array 500, despite the lack of physical separation of the corresponding pixel regions of the active layer 502a or the first semiconductor layer 502b. The lack of physical separation between pixel regions, e.g., the lack of etched edges of the active layer 502a, reduces the fraction of charge carriers that recombine nonradiatively and therefore fail to produce light.

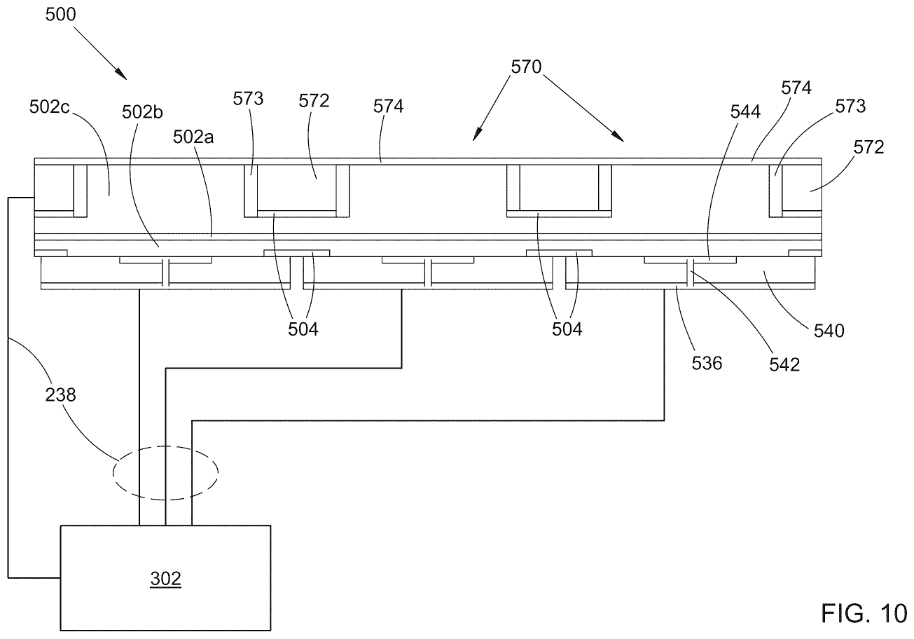

In some examples each outcoupling structure 570 can be arranged with substantially vertical lateral surfaces (e.g., as in the examples of FIGS. 10, 11, 13, 15, 17, 19, and 21). Such outcoupling structures 570 can have the shape of, e.g., a cylinder, a rectangular prism, or a polygonal prism. Such an arrangement can in some instances result in improved luminance. In some other examples each outcoupling structure 570 can be arranged with inclined lateral surfaces so that the outcoupling structure is tapered (e.g., as in the examples of FIGS. 9, 12, 14, 16, 18, and 20). Such an arrangement can in some instances result in improved flux output. Examples of suitable tapered shapes for the outcoupling structures 570 can include, e.g., a frusto-conical shape, a frusto-pyramidal shape, a spherical cap or frustum (i.e., spherical segment), a paraboloidal cap or frustum, a spheroidal cap or frustum, an ellipsoidal cap or frustum, or an ovoidal cap or frustum. It should be noted that the drawings show side cross-section views, and so the shapes depicted cannot be unambiguously determined. FIGS. 9, 12, 14, 16, 18, and 20 depict examples of outcoupling structures 570 characterized by single shapes that could be frusto-conical or frusto-pyramidal. In FIG. 9-21 depict examples that could have rotational symmetry, or not. In some examples each outcoupling structure 570 can be characterized by a single shape.

In some examples (not shown) each outcoupling structure 570 can be characterized by multiple different shapes, e.g., a first shape at the base of the outcoupling structure 570 at the surface of the semiconductor layer 502c, and a second shape separated from the base by the first shape. In some examples the first portion of each outcoupling structure 570 near the base has a steeper slope than a second portion that is separated from the base by the first portion. In some examples, an angular distribution of light emitted from the layer 502a toward the outcoupling structure 570 can be employed to guide the arrangement of the outcoupling structures 570. In a specific example, if an angular emission distribution had local maxima at two different angles, the corresponding portions of the outcoupling structure 570 could be arranged (e.g., by varying the slope angle) to redirect corresponding portions of the angular emission distribution in corresponding desired directions. Many suitable arrangements can be employed.

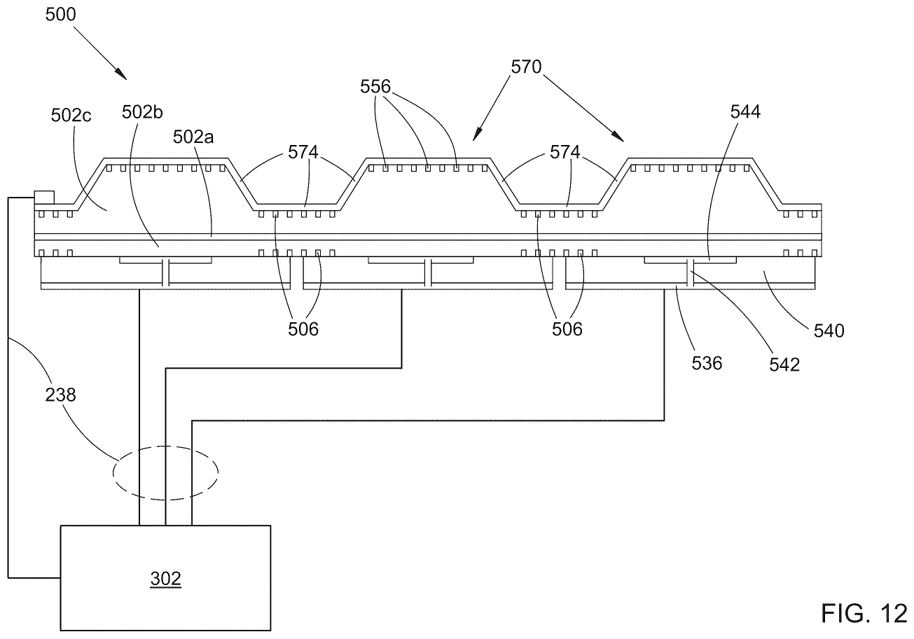

In some examples (e.g., as in FIGS. 12, 13, and 16-21) each outcoupling structure 570 can include a set of nanostructured scattering elements 556 arranged to redirect at least some of the light emitted by the active layer 502a to exit the outcoupling structure 570 and propagate away from the array 500. Such a set of nanostructured scattering elements 556 can be arranged collectively, with respect to the nominal emission wavelength λ₀, for, e.g., non-refractive transmissive redirection of the light exiting the outcoupling structure 570 to result in a narrowed angular distribution of the emission, or increasing the fraction of light that exits the outcoupling structure 570. Other arrangements of the nanostructured scattering elements 556 can be employed, or the nanostructured scattering elements 556 can be employed for other purposes. Suitable structures and materials for the scattering elements 556 are discussed below.

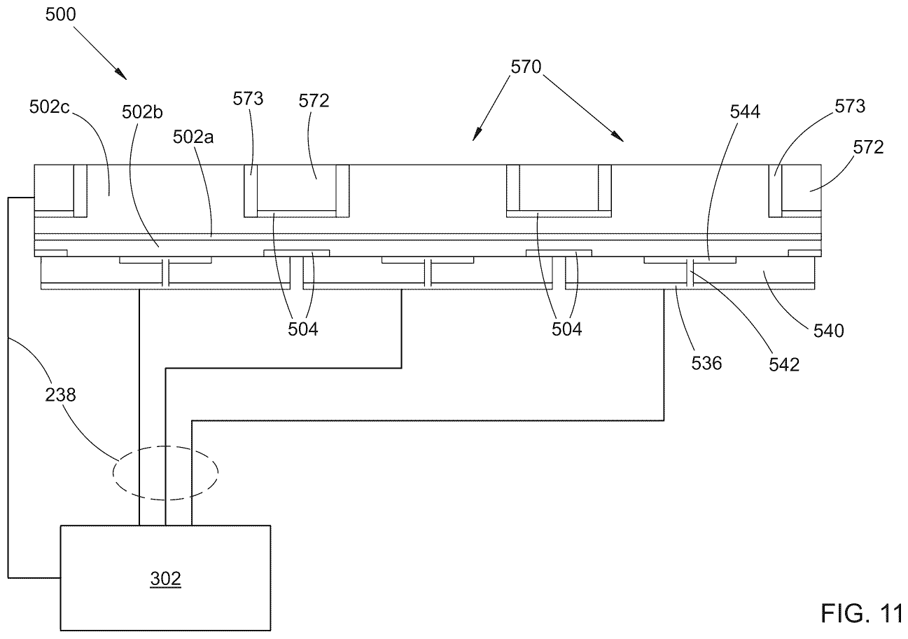

One or more second electrical contacts provide an electrical connection to the semiconductor layer 502c, and can be arranged in any suitable way. In some examples (e.g., as in FIGS. 9, 10, 12, 14, 16, 16, and 20) the second electrical contacts can include a transparent second electrode layer 574 on the first surface of the second semiconductor layer 502c and the outcoupling structure 570. The transparent second electrode layer 574 can include one or more of indium tin oxide (ITO), indium zinc oxide (IZO), or other suitable transparent conductive oxide (TCO). In some of those examples (e.g., as in FIG. 10) the second electrical contacts can also include an electrically conductive second contact layer 572 for connecting the second electrode layer 574 to, e.g., a conductive trace 238. Although the second contact layer 572 appears discontinuous in the drawings (because they are cross-section through the light-emitting elements), the layer 572 nevertheless can be arranged to surround and connect all of the light-emitting elements. In some examples (e.g., as in FIG. 10) an insulating dielectric layer 573 separates the second contact layer 572 and the lateral surface of the outcoupling structure 570. In some examples the second contact layer 572 can include one or more of aluminum, silver, gold, or other suitable metal. In some other examples a transparent second electrode layer is absent (e.g., as in FIGS. 11, 13, 15, 17, 19, and 21); the second contact can instead comprise a second contact layer 572 in electrical contact with the second semiconductor layer 502c only on those portions of the first surface thereof between the multiple outcoupling structures 570, and an insulating dielectric layer 573 separates the second contact layer 572 and the lateral surface of the outcoupling structure 570. In any example having a metal second contact layer 572 covering those portions of the second semiconductor layer 502c between the outcoupling structures 570, the metal second contact layer 572 can also act as an optical absorber for light propagating between pixel regions, and can also prevent that light from exiting the second semiconductor layer 502c from those regions, each of which can potentially improve contrast between adjacent pixel regions. The one or more secondary electrical contacts can be connected to a conductive trace 238 in any suitable way, e.g., secondary via(s) passing through and electrically insulated from the layers 502b/502a/502c, edge contact(s), or peripheral areal contact(s).

In some examples reduced thickness of the semiconductor layers 502b and 502c in regions between the outcoupling structures 570 (e.g., combined thickness less than 2 microns or less than 1 micron) can improve contrast between adjacent pixel regions. Reduced distance between the first electrode layer 544 and the active layer 502a can reduce lateral diffusion of charge carriers in the first semiconductor layer 502b before they reach the active layer 502a. Reduced thickness of the combined layers reduces the solid angle available for light emitted by the active layer 502a to propagate laterally toward an adjacent pixel. In some examples the first surface of the first semiconductor layer 502b, or the first surface and the second semiconductor layer 502c, or both, can have portions between the pixel regions that are structurally arranged so as to reduce or prevent propagation of at least some of the emitted light. In some of those examples, one or more optically absorptive layers 504 can be positioned (i) on portions of the first surface of the first semiconductor layer 502b between the pixel regions, or (ii) on portions of the first surface of the second semiconductor layer 502c between the pixel regions. The optically absorptive layers 504 can be arranged to absorb at least some of the light emitted by the active layer 502a that propagates out of the pixel region through the semiconductor layers. In examples wherein the second electrical contacts are located between the outcoupling structure 570, the optical absorber on the surface of the second semiconductor layer 502c can also act as an ohmic contact layer between the second semiconductor layer 502c and the second contact layer 572.

For any light that does leave the pixel region, the thin semiconductor layers 502b/502a/502c can act as a waveguide. Accordingly, in some examples (e.g., as in FIG. 12) one or more sets of nanostructured scattering elements 506 can be positioned (i) on portions of the first surface of the first semiconductor layer 502b between the pixel regions, or (ii) on portions of the first surface of the second semiconductor layer 502c between the pixel regions. The nanostructured scattering elements 506 can be arranged to reduce or prevent propagation of at least some light emitted from the active layer 502a of one pixel region to an adjacent pixel region through the semiconductor layers 502b/502a/502c. The nanostructured scattering elements 506 can be arranged collectively, with respect to the nominal emission wavelength λ₀, for reducing or prevent propagation of emitted light in one or optical modes supported by the semiconductor layers 502b/502a/502c. Suitable structures and materials for the scattering elements 506 are discussed below.

In some examples each pixel region of the light-emitting array 500 can include a transparent, electrically insulating, dielectric layer 540, and an electrical conductive first contact layer 536. The dielectric layer 540 can be positioned on the first surface of the first semiconductor layer 502b opposite the corresponding outcoupling structure 570. The corresponding first electrode layer 544 can be transparent and positioned between the first semiconductor layer 502b and the dielectric layer 504, and can include ITO, IZO, or other suitable TCO. The first contact layer 536 can be positioned on the dielectric layer 540 opposite the first electrode layer 544 and can include aluminum, silver, gold, or other suitable metal. The first contact layer 536 can be electrically connected to the first electrode layer 544 to form the corresponding independent first electrical contact for that pixel region. In some examples (e.g., as in FIGS. 9-16) the first electrode layer 544 and the first contact layer 536 of each pixel region can be electrically connected by one or more electrically conductive vias 542 through the dielectric layer 540. Each via 542 can provide a localized, circumscribed electrical connection between the first electrode layer 544 and the corresponding first contact layer 536, and can include aluminum, silver, gold, or other suitable metal.

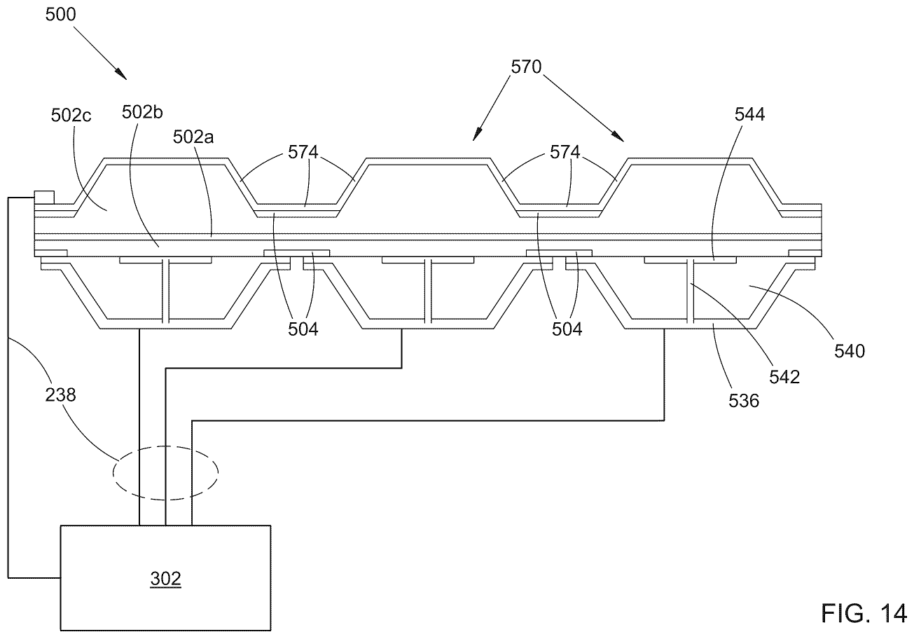

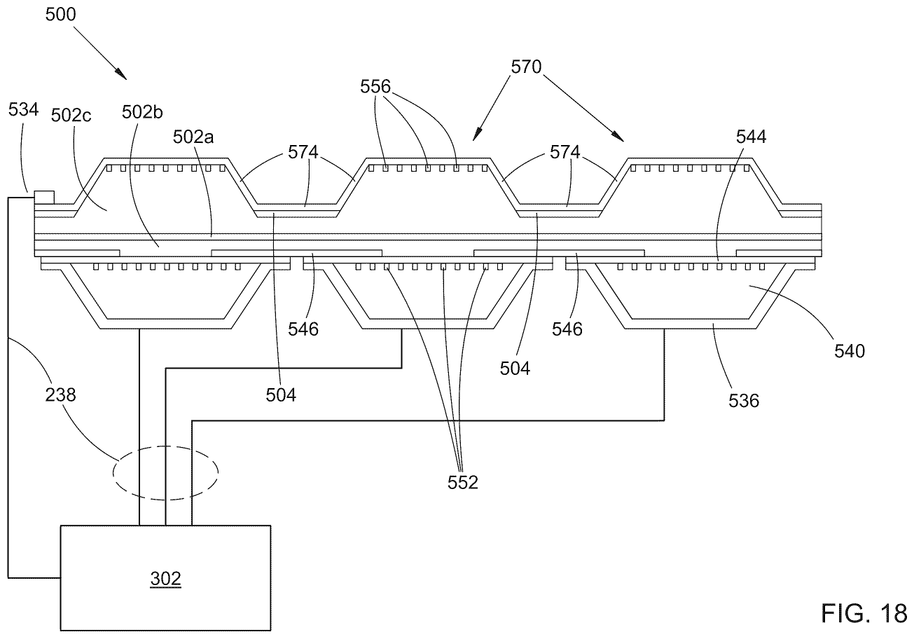

In some examples the corresponding dielectric layer 540 of each pixel region can be in the form of a circumscribed dielectric body 540 that protrudes from the first surface of the first semiconductor layer 502b. In some of those examples the corresponding first electrode layer 544 of each pixel region can be connected to the corresponding first contact layer 536 of that pixel region at a periphery of the dielectric body 540 (e.g., as in the examples of FIGS. 18-21). A dielectric insulating layer 546 can separate peripheral portions of the first electrode layer 544 from the first semiconductor layer 502b, to confine the area of the flow of charge carriers between the first electrode layer 544 and the first semiconductor layer 502b. In some examples (e.g., as in FIGS. 14-21) the dielectric body 540 of each pixel region can have lateral surfaces shaped or inclined to redirect, by one or more internal reflections, at least some of the light emitted by the active layer 502a and propagating through the first dielectric layer 502b to propagate toward the corresponding outcoupling structure 570. Suitable shapes for the dielectric body 540 can include, e.g., a frusto-conical shape, a frusto-pyramidal shape, a spherical cap or frustum (i.e., spherical segment), a paraboloidal cap or frustum, a spheroidal cap or frustum, an ellipsoidal cap or frustum, or an ovoidal cap or frustum. It should be noted that the drawings show side cross-section views, and so the shapes depicted cannot be unambiguously determined.

In some examples (not shown) each dielectric body 540 can be characterized by multiple different shapes, e.g., a first shape at the base of the dielectric body 540 at the surface of the semiconductor layer 502b, and a second shape separated from the base by the first shape. In some examples the first portion of each dielectric body 540 near the base has a steeper slope than a second portion that is separated from the base by the first portion. In some examples, an angular distribution of light emitted from the layer 502a toward the dielectric body 540 can be employed to guide the arrangement of the dielectric body 540. In a specific example, if an angular emission distribution had local maxima at two different angles, the corresponding portions of the dielectric body 540 could be arranged (e.g., by varying the slope angle) to redirect corresponding portions of the angular emission distribution in corresponding desired directions toward the outcoupling structure 570. Many suitable arrangements can be employed.

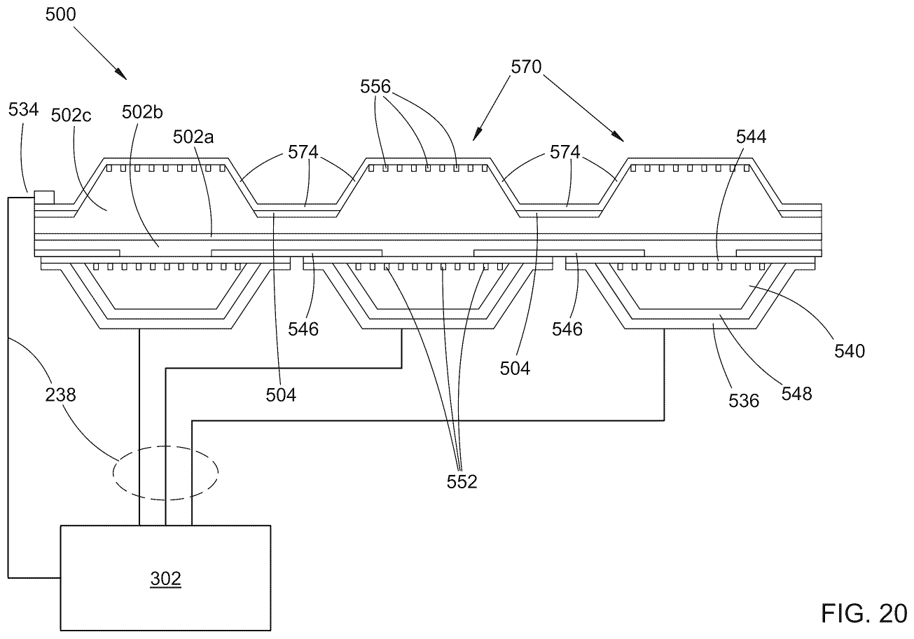

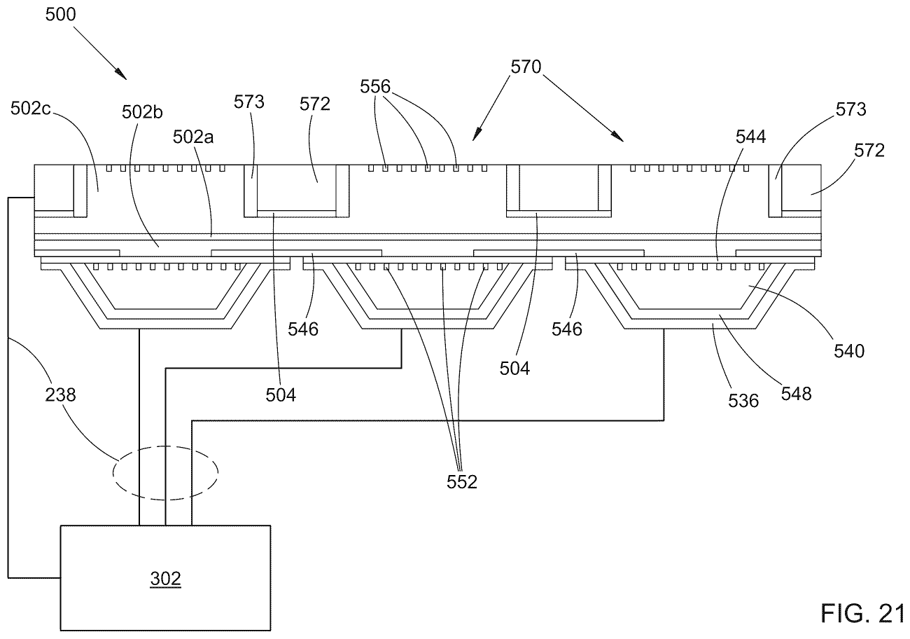

In some examples an optical reflector can be positioned on the dielectric layer 540 opposite the first electrode layer 544. In some examples the first contact layer 536 can act as the optical reflector. In some examples a distinct optical reflector 548 can be positioned between the dielectric body 540 and the first contact layer 536 (e.g., as in FIGS. 20 and 21). The optical reflector 548 can be of any suitable type or arrangement, e.g., a distributed Bragg reflector (DBR) or other multilayer dielectric reflector.

Some examples can include for each pixel region a corresponding set of nanostructured scattering elements 552 positioned between the dielectric layer 540 and the first surface of the first semiconductor layer 502b (e.g., as in FIGS. 18-21) or within the dielectric layer 540 (not shown). The nanostructured scattering elements 552 can be arranged to redirect at least some of the light emitted by the active layer 502b that propagates through the dielectric layer 540 to propagate toward the outcoupling structure 570. Suitable structures and materials for the scattering elements 552 are discussed below.

In some examples the nonzero spacing of the pixel regions of the array 500 can be less than 1.0 mm, less than 0.5 mm, less than 0.3 mm, less than 0.2 mm, less than 0.1 mm, less than 0.08 mm, less than 0.05 mm, less than 0.03 mm, less than 0.02 mm, or less than 0.01 mm. In some examples the nonzero separation between adjacent first electrical contacts can be less than 50 μm, less than 20 μm, less than 10 μm, less than 5 μm, less than 2 μm, less than 1.0 μm, or less than 0.05 μm.

In some examples the array 500 can be arranged so that some or all of the pixel regions thereof act as direct emitters, i.e., light emitted from the junction or active layer 502a being the output of those pixel regions. In some examples the array 500 can include one or more wavelength-converting structures (e.g., phosphor wavelength converters) on one or more or all of the pixel regions, so that output of those pixel regions includes down-converted light emitted by the wavelength-converting structure (with or without residual light emitted by the junction or active layer 502a). In some examples such wavelength-converting structures can all emit at the same one or more wavelengths; in other examples wavelength-converting structures of some pixel regions can emit at wavelengths different from those emitted by wavelength-converting structures of some other pixel regions. In some examples the wavelength-converting structures can be arranged as discrete elements on each pixel region; in some other examples the wavelength-converting structures can be corresponding areas of a contiguous layer over multiple pixel regions, or over all of the pixel regions.

The corresponding transparent electrode layers 544 of the multiple first electrical contacts can be separated from one another by air gaps or by electrically insulating material so as to substantially prevent direct electrical conduction between adjacent first electrical contacts. In some examples the corresponding electrically conductive layers 536 of the multiple first electrical contacts can be separated from one another by air gaps or by electrically insulating material so as to substantially prevent direct electrical conduction between adjacent first electrical contacts. In some examples a set of multiple independent electrically conductive traces or interconnects 238 can be connected to the first electrical contacts (e.g., to the layers 536). In some examples each first electrical contact can be connected to a single corresponding one of the traces or interconnects 238 that is different from a corresponding trace or interconnect 238 connected to any other first electrical contact. In such examples each pixel region can be independently addressable.

In some examples each dielectric layer or body 540, and each electrically insulating layer 546 or reflector 548 (if present) can include one or more materials among: doped or undoped silicon oxide, nitride, or oxynitride; one or more doped or undoped semiconductor oxides, nitrides, or oxynitrides; or one or more doped or undoped metal or transition metal oxides, nitrides, or oxynitrides. In some examples each insulating layer 540 (or 546, if present) can include oxidized or otherwise passivated material of the first semiconductor layer 502b; in other examples each insulating layer or body 540 (or insulating layer 546 or reflector 548, if present) can be formed from material grown, deposited, or otherwise formed on the semiconductor layer 502b. In some examples the nonzero thickness of the dielectric layers or bodies 540 can be less than 10 μm, less than 5 μm, less than 3 μm, less than 2 μm, less than 1.5 μm, or less than 1.0 μm. In some examples it can be desirable to limit refractive index contrast between the dielectric layers or bodies 540 and the semiconductor layer 502b, to facilitate entry if emitted light into the dielectric layers or bodies 540 for collection, collimation, or redirection. Accordingly, in some examples the difference between respective refractive indices of the first semiconductor layer 502b and the dielectric layers or bodies 540 can be less than 0.5, less than 0.4, less than 0.3, less than 0.2, or less than 0.1.

In the examples of FIGS. 12, 13, and 16-21, one or more sets of multiple nanostructured optical elements are depicted that can be employed to redirect emitted light within and out of the array 500. In some examples (e.g., as in FIGS. 18-21), a set of multiple nanostructured optical elements 552 can be positioned between the first semiconductor layer 502b and the dielectric layer or body 540 or within the dielectric layer or body 540. In some examples (e.g., as in FIGS. 12, 13, and 16-21), a set of multiple nanostructured optical elements 556 can be positioned on the outcoupling structures 570. In some examples (e.g., as in FIG. 12), a set of multiple nanostructured optical elements 506 can be positioned (i) on portions of the first surface of the first semiconductor layer 502b between the pixel regions, or (ii) on portions of the first surface of the second semiconductor layer 502c between the pixel regions, or both. Each such set of nanostructured elements can be arranged as described below independently of the arrangement of other sets that might be present (e.g., if sets of elements 552 and sets of elements 556 are both present, the arrangement and composition of each set would be independent of the other, except that they would both be referenced to the same nominal output wavelength λ₀.

Each nanostructured optical element 506/552/556 can be arranged as one or more volumes of dielectric material protruding into or embedded in another medium, material, or layer (e.g., the first or second semiconductor layer 502b/502c, the corresponding dielectric layer or body 540, or an ambient medium), and can be characterized by a corresponding element size relative to the nominal emission vacuum wavelength λ₀ and by an element shape. The nanostructured optical elements 506/552/556 can be arranged as corresponding arrays of elements characterized by at least one element spacing relative to the nominal emission vacuum wavelength λ₀.

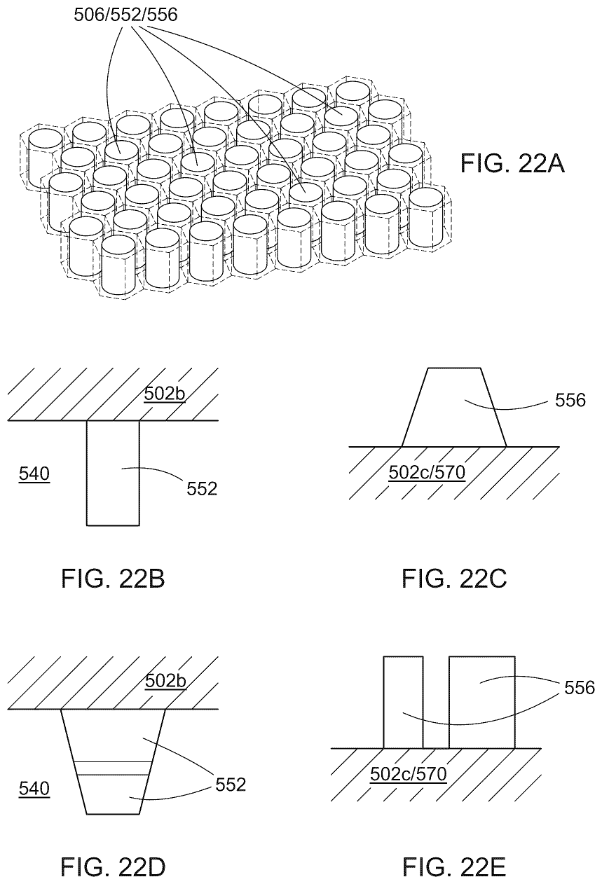

In some examples each set of nanostructured elements 506/552/556 can include a multitude of suitably sized and shaped projections, holes, depressions, inclusions, or structures, or they can be arranged as an array of single or double nano-antennae, a partial photonic bandgap structure, a photonic crystal, or an array of meta-atoms or meta-molecules. Various examples are depicted schematically in FIGS. 22A-22E. In some examples size or spacing of the nanostructured elements 506, 552, or 556 can be (i) less than λ₀/n_{D}, less than λ₀/2n_{D}, less than λ₀/4n_{D}, or less than λ₀/10n_{D} (n_{D} being the refractive index of the dielectric body 540), (ii) less than λ₀/n_{SC1}, less than λ₀/2n_{SC1}, less than λ₀/4n_{SC1}, or less than λ₀/10n_{SC1} (n_{SC1} being the refractive index of the first semiconductor layer 502b), or (iii) less than λ₀/n_{SC2}, less than λ₀/2n_{SC2}, less than λ₀/4_{SC2}, or less than λ₀/10n_{SC2} (n_{SC2} being the refractive index of the second semiconductor layer 502c). In some examples the nanostructured elements 506, 552, or 556 can include one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped metal or transition metal oxides, nitrides, or oxynitrides; one or more doped or undoped semiconductor oxides, nitrides, or oxynitrides; one or more optical glasses; or one or more doped or undoped polymers. In some examples the nanostructured elements 506, 552, or 556 can be arranged as a periodic array, e.g., a rectangular, hexagonal, or trigonal array. In some examples the nanostructured elements 506, 552, or 556 can be arranged in an irregular or aperiodic arrangement.

The arrangement of the first electrode layer 544 and the outcoupling structure 570 and (if present) one or more of the first contact layer 536, the electrically insulating layers 546, or the nanostructured elements 506/552/556 can enable achievement of, inter alia, (i) a sufficiently large contrast ratio between adjacent pixel regions, (ii) a sufficiently large fraction of light emitted within a given pixel region to exit the array from that pixel region, or (iii) a sufficiently small fraction of light emitted within a given pixel region to exit the array from any different pixel regions. In some examples the pixel regions of the array 500 can exhibit a contrast ratio for emitted light exiting from adjacent pixel regions that is greater than 5:1, greater than 10:1, greater than 20:1, greater than 50:1, greater than 100:1, or greater than 300:1. In some examples the fraction of light emitted within each pixel region that exits the array 500 from that pixel area can be greater than 50%, greater than 75%, greater than 90%, greater than 95%, greater than 98%, or greater than 99%. In some examples the fraction of light emitted within each pixel region exits the array 500 from any different pixel region can be less than 50%, less than 25%, less than 10%, less than 5%, less than 2%, or less than 1%.

Design or optimization one or more or all of the diode structure (layers 502a/502b/502c), the outcoupling structures 570 (size, shape), the transparent electrode layers 544, and (if present) the dielectric layers or bodies 540 (size, shape, refractive index), the first contact layers 536, the vias 542, the reflectors 548, or the nanostructured elements 506/552/556 can be performed (by calculation, simulation, or iterative designing/making/testing of prototypes or test devices) based on one or more selected figures-of-merit (FOMs). Device-performance-based FOMs that can be considered can include, e.g.: (i) overall efficiency of light emission relative to input electrical current; (ii) radiated emission angular distribution of the emitted light; (iii) contrast ratio between adjacent pixel regions for light emission, or (iv) other suitable or desirable FOMs. Instead or in addition, reduction of cost or manufacturing complexity can be employed as an FOM in a design or optimization process. Optimization for one FOM can result in non-optimal values for one or more other FOMs. Note that a device that is not necessarily fully optimized with respect to any FOM can nevertheless provide acceptable enhancement of one or more FOMs; such partly optimized devices fall within the scope of the present disclosure or appended claims.

In some examples the light-emitting array 500 can include a set of multiple independent electrically conductive traces or interconnects 238 connected to the first electrical contacts. In some examples each first electrical contact can be connected to a single corresponding one of the traces or interconnects 238 that is different from a corresponding trace or interconnect 238 that is connected to at least one other first electrical contact. In some examples each first electrical contact can be connected to a single corresponding one of the traces or interconnects 238 that is different from all corresponding traces or interconnects 238 that are connected to any other first electrical contacts, so that the pixel regions are independently addressable. In some examples the light-emitting array 500 can include a drive circuit 302 connected, by the electrical traces or interconnects 238, to the first electrical contacts through the corresponding conductive layers 536 and to the second electrical contacts 234. The drive circuit 302 can be structured and connected so as to provide electrical drive current that flows through the array 500 and causes the array 500 to emit light. The drive circuit can be further structured and connected so that (i) corresponding portions of the electrical drive current flow through one or more corresponding pixel regions as corresponding pixel currents, and (ii) each pixel current magnitude differs from the corresponding pixel current magnitude of at least one other of the pixel regions of the array 500.

In some examples, a method for using the light-emitting array 500 (in any of the arrangements shown or described) can include selecting a first specified spatial distribution of pixel current magnitudes, and operating the drive circuit 302 to provide those pixel current magnitudes to the corresponding pixel regions of the array 500, causing the array to emit light according to a corresponding first spatial distribution of light emission intensity across the array 500. A second specified spatial distribution of pixel current magnitudes, different from the first, can then be selected, and the drive circuit 302 can be operated to provide the second specified spatial distribution of pixel current magnitudes to the pixel regions of the array 500, causing the array to emit light according to a corresponding second spatial distribution of light emission intensity across the array 500 that differs from the first spatial distribution of light emission intensity.

In some examples, a method for making the light-emitting array 500 (in any of the arrangements shown or described) can include forming the second semiconductor layer 502c on a fabrication substrate (e.g., a sapphire substrate), forming the active layer 502a on the second semiconductor layer 502c, and then forming the first semiconductor layer 502b on the active layer 502a. Any suitable processes can be employed to grow, deposit, or otherwise form those layers. While still attached to the sapphire substrate, the first electrode layers 544 are formed on the semiconductor layer 502b, along with (if present) one or more of the dielectric layer 540, the nanostructured scattering elements 506 or 552, the vias 542, the first contact layers 536, or the reflectors 548. Any suitable spatially selective material processing techniques can be employed. After separating the semiconductor layers 502b/502a/502c from the sapphire substrate, the entire structure is flipped over for processing the second semiconductor layer 502c to form the outcoupling structures 570, along with (if present) the second contact layer 572, the dielectric elements 573, the second electrode layer 574, the absorber 504, or the nanostructured scattering elements 506 or 556. Any suitable spatially selective material processing techniques can be employed.

In addition to the preceding, the following example embodiments fall within the scope of the present disclosure or appended claims. Any given Example below that refers to on or more or all preceding Examples shall be understood to refer to only those preceding Examples with which the given Example is not inconsistent, and to exclude those preceding Examples with which the given Example is inconsistent.

Example 1. A semiconductor light-emitting array comprising: first and second doped semiconductor layers that are arranged for emitting light at a nominal emission vacuum wavelength λ₀ resulting from carrier recombination at a junction or active layer between the first and second semiconductor layers, the first and second semiconductor layers and the junction or active layer being coextensive over a contiguous area of the array; a set of multiple outcoupling structures that comprise protruding portions of the second semiconductor layer that protrude away from a first surface thereof opposite the first semiconductor layer and are structurally arranged so as to collect or redirect at least some of the light emitted by the active layer to exit the outcoupling structure and propagate away from the array; on a first surface of the first semiconductor layer opposite the second semiconductor layer, and opposite each outcoupling structure, a corresponding circumscribed electrically conductive first electrode layer in electrical contact with the first semiconductor layer at the first surface thereof so as to form at least a portion of a corresponding one of multiple, independent first electrical contacts; and one or more second electrical contacts in electrical contact with the second semiconductor layer, each outcoupling structure and the corresponding first electrical contact defining a corresponding discrete, circumscribed pixel region within the contiguous area of the array that is separated from other circumscribed pixel regions of the array.

Example 2. The light-emitting array of Example 1, each outcoupling structure being arranged with substantially vertical lateral surfaces.

Example 3. The light-emitting array of Example 1, each outcoupling structure being arranged with inclined lateral surfaces so that the outcoupling structure is tapered.

Example 4. The light-emitting array of Example 3, each dielectric body including a frusto-conical shape or a frusto-pyramidal shape.

Example 5. The light-emitting array of any one of Examples 3 or 4, each outcoupling structure including a shape of a spherical cap or frustum, a paraboloidal cap or frustum, a spheroidal cap or frustum, an ellipsoidal cap or frustum, or an ovoidal cap or frustum.

Example 6. The light-emitting array of any one of Examples 3 through 5, each outcoupling structure including a first portion with a first shape and a second portion with a second shape different from the first shape, the first portion being between the second portion and the second semiconductor layer.

Example 7. The light-emitting array of Example 6, the first and second shapes being arranged so as to transmit or redirect corresponding first and second portions of an angular distribution of the light emitted by the active layer to exit the outcoupling structure and propagate away from the array.

Example 8. The light-emitting array of any one of Examples 1 through 7, each outcoupling structure including on at least a portion thereof a transparent, electrically conductive, second electrode layer in electrical contact with the second semiconductor layer, the second electrode layer forming at least a portion of the one or more second electrical contacts.

Example 9. The light-emitting array of Example 8, the transparent second electrode layer including one or more of indium tin oxide, indium zinc oxide, one or more other transparent conductive oxides, or combinations or mixtures thereof.

Example 10. The light-emitting array of any one of Examples 1 through 7, the one or more second electrical contacts being in electrical contact with the second semiconductor layer only on those portions of the first surface thereof between the multiple outcoupling structures.

Example 11. The light-emitting array of any one of Examples 1 through 10, each second electrical contact including one or more of aluminum, silver, gold, other metals or metal alloys, or combinations thereof.

Example 12. The light-emitting array of any one of Examples 1 through 11, each first electrode layer including one or more of aluminum, silver, gold, other metals or metal alloys, or combinations thereof.

Example 13. The light-emitting array of any one of Examples 1 through 11 further comprising, for each pixel region: (i) a corresponding electrically insulating, transparent, dielectric layer on the first surface of the first semiconductor layer opposite the corresponding outcoupling structure, the corresponding first electrode layer being transparent and positioned between the first semiconductor layer and the dielectric layer; and (ii) a corresponding electrically conductive first contact layer on the dielectric layer opposite the first electrode layer and electrically connected to the first electrode layer so as to form the corresponding independent first electrical contact.

Example 14. The light-emitting array of Example 13, each transparent first electrode layer including one or more of indium tin oxide, indium zinc oxide, one or more other transparent conductive oxides, or combinations or mixtures thereof.

Example 15. The light-emitting array of any one of Examples 13 or 14, each dielectric layer including one or more materials among: doped or undoped silicon oxide, nitride, or oxynitride; one or more doped or undoped semiconductor oxides, nitrides, or oxynitrides; one or more doped or undoped metal or transition metal oxides, nitrides, or oxynitrides; one or more optical glasses; or one or more doped or undoped polymers.

Example 16. The light-emitting array of any one of Examples 13 through 15, nonzero thickness of the dielectric layers being less than 10 μm, less than 5 μm, less than 3 μm, less than 2 μm, less than 1.5 μm, or less than 1 μm.

Example 17. The light-emitting array of any one of Examples 13 through 16, the corresponding first electrode layer of each pixel region being connected to the corresponding first contact layer of that pixel region by one or more electrically conductive vias through the corresponding dielectric layer, each via providing a localized, circumscribed electrical connection between the corresponding first electrode layer and the corresponding first contact layer.

Example 18. The light-emitting array of any one of Examples 13 through 17, each first contact layer including one or more of aluminum, silver, gold, other metals or metal alloys, or combinations thereof.

Example 19. The light-emitting array of any one of Examples 13 through 18, the one or more electrically conductive vias of each first electrical contact including one or more of aluminum, silver, gold, other metals or metal alloys, or combinations thereof.

Example 20. The light-emitting array of any one of Examples 1 through 19, the corresponding first electrical contacts being separated from one another by air gaps or by electrically insulating material so that direct electrical conduction between adjacent first electrical contacts is substantially prevented.

Example 21. The light-emitting array of any one of Examples 13 through 16, the corresponding dielectric layer of each pixel region being a circumscribed dielectric body, and the corresponding first electrode layer of each pixel region being connected to the corresponding first contact layer of that pixel region at a periphery of the dielectric body.

Example 22. The light-emitting array of any one of Examples 13 through 21, the corresponding dielectric layer of each pixel region being a circumscribed dielectric body that is structurally arranged so as to redirect at least some of the light emitted by the active layer that propagates through the dielectric layer to propagate toward the corresponding outcoupling structure.

Example 23. The light-emitting array of Example 22, each dielectric body including a frusto-conical shape or a frusto-pyramidal shape.

Example 24. The light-emitting array of any one of Examples 22 or 23, each dielectric body including a shape of a spherical cap or frustum, a paraboloidal cap or frustum, a spheroidal cap or frustum, an ellipsoidal cap or frustum, or an ovoidal cap or frustum.

Example 25. The light-emitting array of any one of Examples 22 through 24, each dielectric body including a first portion with a first shape and a second portion with a second shape different from the first shape, the first portion being between the second portion and the first semiconductor layer.

Example 26. The light-emitting array of Example 25, the first and second shapes being arranged so as to redirect corresponding first and second portions of an angular distribution of emitting light to propagate in corresponding selected directions to exit the dielectric body and propagate toward the corresponding outcoupling structure.

27. The light-emitting array of any one of Examples 13 through 26 further comprising, for each pixel region, an optical reflector on the dielectric layer opposite the first electrode layer.

Example 28. The light-emitting array of any one of Examples 13 through 27, further comprising on each dielectric layer a corresponding reflective coating between the dielectric layer and the corresponding first contact layer.

Example 29. The light-emitting array of Example 28, the reflective coating including a multilayer reflective coating or a distributed Bragg reflector (DBR).

Example 30. The light-emitting array of any one of Examples 29 or 30, the reflective coating including one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped semiconductor oxides, nitrides, or oxynitrides; one or more doped or undoped metal or transition metal oxides, nitrides, or oxynitrides; one or more optical glasses; or one or more doped or undoped polymers.

Example 31. The light-emitting array of any one of Examples 1 through 30, the first surface of the first semiconductor layer, or the first surface and the second semiconductor layer, or both, having portions thereof between the pixel regions that are structurally arranged so as to reduce or prevent propagation of at least some light emitted from the active layer of one pixel region to an adjacent pixel region through the semiconductor layers.

Example 32. The light-emitting array of Example 31 further comprising one or more optically absorptive layers positioned (i) on portions of the first surface of the first semiconductor layer between the pixel regions, or (ii) on portions of the first surface of the second semiconductor layer between the pixel regions, the one or more optically absorptive layers being arranged so as to absorb at least some of the light emitted by the active layer that propagates out of the corresponding pixel region through the semiconductor layers.

Example 33. The light-emitting array of any one of Examples 31 or 32 further comprising one or more sets of nanostructured scattering elements positioned (i) on portions of the first surface of the first semiconductor layer between the pixel regions, or (ii) on portions of the first surface of the second semiconductor layer between the pixel regions, the one or more sets of nanostructured scattering elements being arranged so as to reduce or prevent propagation of at least some light emitted from the active layer of one pixel region to an adjacent pixel region through the semiconductor layers.

Example 34. The light-emitting array of any one of Examples 1 through 33, each outcoupling structure including a set of nanostructured scattering elements arranged so as to redirect at least some of the light emitted by the active layer to exit the outcoupling structure and propagate away from the array.

Example 35. The light-emitting array of any one of Examples 1 through 34 further comprising, for each pixel region, a corresponding set of nanostructured scattering elements positioned within the dielectric layer or between the dielectric layer and the first semiconductor layer, the nanostructured scattering elements being arranged so as to redirect at least some of the light emitted by the active layer that propagates through the dielectric layer to propagate toward the outcoupling structure.

Example 36. The light-emitting array of any one of Examples 33 through 35, the nanostructured elements of any one or more or all of the recited sets of nanostructured elements including a multitude of suitably sized and shaped projections, holes, depressions, inclusions, ridges, trenches, or structures.

Example 37. The light-emitting array of any one of Examples 33 through 36, the nanostructured elements of any one or more or all of the recited sets of nanostructured elements including an array of single or double nano-antennae, a partial photonic bandgap structure, a photonic crystal, or an array of meta-atoms or meta-molecules.

Example 38. The light-emitting array of any one of Examples 33 through 37, nonzero size or spacing of the nanostructured elements of any one or more or all of the recited sets of nanostructured elements being less than λ₀/n, less than λ₀/2n, less than λ₀/4n, or less than λ₀/10n, n being the refractive index of the dielectric layer or the first or second semiconductor layers.

Example 39. The light-emitting array of any one of Examples 33 through 38, the nanostructured elements of any one or more or all of the recited sets of nanostructured elements including one or more materials among: one or more metals or metal alloys; doped or undoped silicon; one or more doped or undoped III-V, II-VI, or Group IV semiconductors; doped or undoped silicon oxide, nitride, or oxynitride; one or more doped or undoped metal or transition metal oxides, nitrides, or oxynitrides; one or more doped or undoped semiconductor oxides, nitrides, or oxynitrides; one or more optical glasses; or one or more doped or undoped polymers.

Example 40. The light-emitting array of any one of Examples 1 through 39, the nominal emission vacuum wavelength λ₀ being greater than 0.20 μm, greater than 0.4 μm, greater than 0.8 μm, less than 10. μm, less than 2.5 μm, or less than 1.0 μm.

Example 41. The light-emitting array of any one of Examples 1 through 40, the first and second semiconductor layers and the junction or active layer forming a semiconductor light-emitting diode structure.

Example 42. The light-emitting array of any one of Examples 1 through 41, the first and second semiconductor layers including one or more doped or undoped III-V, II-VI, or Group IV semiconductor materials or alloys or mixtures thereof.

Example 43. The light-emitting array of any one of Examples 1 through 42, the junction or active layer including one or more doped or undoped III-V, II-VI, or Group IV semiconductor materials or alloys or mixtures thereof.

Example 44. The light-emitting array of any one of Examples 1 through 43, the junction or active layer including one or more p-n junctions, one or more quantum wells, one or more multi-quantum wells, or one or more quantum dots.

Example 45. The light-emitting array of any one of Examples 1 through 44, the pixel regions of the array exhibiting a contrast ratio for emitted light exiting from adjacent pixel regions that is greater than 5:1, greater than 10:1, greater than 20:1, greater than 50:1, greater than 100:1, or greater than 300:1.

Example 46. The light-emitting array of any one of Examples 1 through 45, nonzero spacing of the pixel regions of the array being less than 1.0 mm, less than 0.5 mm, less than 0.3 mm, less than 0.2 mm, less than 0.10 mm, less than 0.08 mm, less than 0.05 mm, less than 0.03 mm, less than 0.02 mm, or less than 0.010 mm.

Example 47. The light-emitting array of any one of Examples 1 through 46, nonzero separation between adjacent first electrical contacts being less than 50 μm, less than 20 μm, less than 10 μm, less than 5 μm, less than 2 μm, less than 1 μm, or less than 0.5 μm.

Example 48. The light-emitting array of any one of Examples 1 through 47, nonzero total thickness of the first and second semiconductor layers and the junction or active layer, between the outcoupling structures, being less than 10 μm, less than 5 μm, less than 3 μm, less than 2 μm, less than 1.5 μm, or less than 1 μm.

Example 49. The light-emitting array of any one of Examples 1 through 48, the pixel regions of the array being arranged so that, of the light emitted within each pixel region at the nominal emission vacuum wavelength λ₀ and that exits the array through the second semiconductor layer, at least a specified minimum fraction of the exiting light exits from that pixel area, and the specified minimum fraction is greater than 50%, greater than 75%, greater than 90%, greater than 95%, greater than 98%, or greater than 99%.

Example 50. The light-emitting array of any one of Examples 1 through 49, the pixel regions of the array being arranged so that, of the light emitted within each pixel region at the nominal emission vacuum wavelength λ₀ and that exits the array through the second semiconductor layer, at most a specified maximum fraction of the exiting light exits the array from other, different pixel region, and the specified maximum fraction is less than 50%, less than 25%, less than 10%, less than 5%, less than 2%, or less than 1%.

Example 51. The light-emitting array of any one of Examples 1 through 50 further comprising: a set of multiple independent electrically conductive traces or interconnects connected to the first electrical contacts, each first electrical contact being connected to a single corresponding one of the traces or interconnects that is different from a corresponding trace or interconnect connected to at least one other first electrical contact; and a drive circuit connected to the first and second electrical contacts by the electrical traces or interconnects, the drive circuit being structured and connected so as to provide electrical drive current that flows through the array and causes the array to emit light, and that is further structured and connected so that (i) corresponding portions of the electrical drive current flow through one or more corresponding pixel regions as corresponding pixel currents, and (ii) each pixel current magnitude differs from the corresponding pixel current magnitude of at least one other of the pixel regions of the array.

Example 52. A method for using the light-emitting array of Example 51, the method comprising: (A) selecting a first specified spatial distribution of pixel current magnitudes; (B) operating the drive circuit to provide the first specified spatial distribution of pixel current magnitudes to the pixel regions of the array, causing the array to emit light according to a corresponding first spatial distribution of light emission intensity across the array; (C) selecting a second specified spatial distribution of pixel current magnitudes that differs from the first specified spatial distribution of pixel current magnitudes; and (D) operating the drive circuit to provide the second specified spatial distribution of pixel current magnitudes to the pixel regions of the array, causing the array to emit light according to a corresponding second spatial distribution of light emission intensity across the array that differs from the first spatial distribution of light emission intensity.

Example 53. A method for making the light-emitting array of Example 51, the method comprising: (A) forming the first and second semiconductor layers with the junction or active layer between them; (B) forming the outcoupling structures on the second semiconductor layer; (C) forming the first electrical contacts in electrical contact with the first semiconductor layer; (D) forming the second electrical contacts in electrical contact with the second semiconductor layer; (E) forming one or more electrical traces or interconnects connected to the sets of first and second electrical contacts; and (F) connecting the drive circuit to the first and second electrical contacts using the electrical traces or interconnects.

Example 54. A method for making the light-emitting array of any one of Examples 1 through 51, the method comprising: (A) forming the first and second semiconductor layers with the junction or active layer between them; (B) forming the outcoupling structures on the second semiconductor layer; (C) forming the first electrical contacts in electrical contact with the first semiconductor layer; and (D) forming the second electrical contacts in electrical contact with the second semiconductor layer.

This disclosure is illustrative and not limiting. Further modifications will be apparent to one skilled in the art in light of this disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of any single disclosed example embodiment. Therefore, the present disclosure shall be construed as implicitly disclosing any embodiment having any suitable subset of one or more features-which features are shown, described, or claimed in the present application-including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either . . . or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each.

For purposes of the present disclosure or appended claims, when a numerical quantity is recited (with or without terms such as “about,” “about equal to,” “substantially equal to,” “greater than about,” “less than about,” and so forth), standard conventions pertaining to measurement precision, rounding error, and significant digits shall apply, unless a differing interpretation is explicitly set forth. For null quantities described by phrases such as “prevented,” “absent,” “eliminated,” “equal to zero,” “negligible,” and so forth (with or without terms such as “substantially” or “about”), each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled.

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim. In the appended claims, if the provisions of 35 USC § 112 (f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC § 112 (f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A semiconductor light-emitting array comprising:
first and second doped semiconductor layers that are arranged for emitting light at a nominal emission vacuum wavelength λ₀ resulting from carrier recombination at a junction or active layer between the first and second semiconductor layers, the first and second semiconductor layers and the junction or active layer being coextensive over a contiguous area of the array;
a set of multiple outcoupling structures that comprise protruding portions of the second semiconductor layer that protrude away from a first surface thereof opposite the first semiconductor layer and are structurally arranged so as to collect or redirect at least some of the light emitted by the active layer to exit the outcoupling structure and propagate away from the array;
on a first surface of the first semiconductor layer opposite the second semiconductor layer, and opposite each outcoupling structure, a corresponding circumscribed electrically conductive first electrode layer in electrical contact with the first semiconductor layer at the first surface thereof so as to form at least a portion of a corresponding one of multiple, independent first electrical contacts; and
one or more second electrical contacts in electrical contact with the second semiconductor layer,
each outcoupling structure and the corresponding first electrical contact defining a corresponding discrete, circumscribed pixel region within the contiguous area of the array that is separated from other circumscribed pixel regions of the array.

2. The light-emitting array of claim 1, each outcoupling structure being arranged with substantially vertical lateral surfaces.

3. The light-emitting array of claim 1, each outcoupling structure being arranged with inclined lateral surfaces so that the outcoupling structure is tapered.

4. The light-emitting array of claim 1, each outcoupling structure including a set of nanostructured scattering elements arranged so as to redirect at least some of the light emitted by the active layer to exit the outcoupling structure and propagate away from the array.

5. The light-emitting array of claim 1, each outcoupling structure including on at least a portion thereof a transparent, electrically conductive, second electrode layer in electrical contact with the second semiconductor layer, the second electrode layer forming at least a portion of the one or more second electrical contacts.

6. The light-emitting array of claim 1, the one or more second electrical contacts being in electrical contact with the second semiconductor layer only on those portions of the first surface thereof between the multiple outcoupling structures.

7. The light-emitting array of claim 1, the first surface of the first semiconductor layer, or the first surface and the second semiconductor layer, or both, having portions thereof between the pixel regions that are structurally arranged so as to reduce or prevent propagation of at least some light emitted from the active layer of one pixel region to an adjacent pixel region through the semiconductor layers.

8. The light-emitting array of claim 7 further comprising one or more optically absorptive layers positioned (i) on portions of the first surface of the first semiconductor layer between the pixel regions, or (ii) on portions of the first surface of the second semiconductor layer between the pixel regions, the one or more optically absorptive layers being arranged so as to absorb at least some of the light emitted by the active layer that propagates out of the corresponding pixel region through the semiconductor layers.

9. The light-emitting array of claim 7 further comprising one or more sets of nanostructured scattering elements positioned (i) on portions of the first surface of the first semiconductor layer between the pixel regions, or (ii) on portions of the first surface of the second semiconductor layer between the pixel regions, the one or more sets of nanostructured scattering elements being arranged so as to reduce or prevent propagation of at least some light emitted from the active layer of one pixel region to an adjacent pixel region through the semiconductor layers.

10. The light-emitting array of claim 1, (i) the first and second semiconductor layers including one or more doped or undoped III-V, II-VI, or Group IV semiconductor materials or alloys or mixtures, and (ii) the junction or active layer including one or more doped or undoped III-V, II-VI, or Group IV semiconductor materials or alloys or mixtures thereof.

11. The light-emitting array of claim 1 further comprising, for each pixel region: (i) a corresponding electrically insulating, transparent, dielectric layer on the first surface of the first semiconductor layer opposite the corresponding outcoupling structure, the corresponding first electrode layer being transparent and positioned between the first semiconductor layer and the dielectric layer; and (ii) a corresponding electrically conductive first contact layer on the dielectric layer opposite the first electrode layer and electrically connected to the first electrode layer so as to form the corresponding independent first electrical contact.

12. The light-emitting array of claim 11, the corresponding first electrode layer of each pixel region being connected to the corresponding first contact layer of that pixel region by one or more electrically conductive vias through the corresponding dielectric layer, each via providing a localized, circumscribed electrical connection between the corresponding first electrode layer and the corresponding first contact layer.

13. The light-emitting array of claim 11, the corresponding dielectric layer of each pixel region being a circumscribed dielectric body, and the corresponding first electrode layer of each pixel region being connected to the corresponding first contact layer of that pixel region at a periphery of the dielectric body.

14. The light-emitting array of claim 11, the corresponding dielectric layer of each pixel region being a circumscribed dielectric body that is structurally arranged so as to redirect at least some of the light emitted by the active layer that propagates through the dielectric layer to propagate toward the corresponding outcoupling structure.

15. The light-emitting array of claim 11 further comprising, for each pixel region, an optical reflector on the dielectric layer opposite the first electrode layer.

16. The light-emitting array of claim 11 further comprising, for each pixel region, a corresponding set of nanostructured scattering elements positioned within the dielectric layer or between the dielectric layer and the first semiconductor layer, the nanostructured scattering elements being arranged so as to redirect at least some of the light emitted by the active layer that propagates through the dielectric layer to propagate toward the outcoupling structure.

17. The light-emitting array of claim 1, further comprising:
a set of multiple independent electrically conductive traces or interconnects connected to the first electrical contacts, each first electrical contact being connected to a single corresponding one of the traces or interconnects that is different from a corresponding trace or interconnect connected to at least one other first electrical contact; and
a drive circuit connected to the first and second electrical contacts by the electrical traces or interconnects, the drive circuit being structured and connected so as to provide electrical drive current that flows through the array and causes the array to emit light, and that is further structured and connected so that (i) corresponding portions of the electrical drive current flow through one or more corresponding pixel regions as corresponding pixel currents, and (ii) each pixel current magnitude differs from the corresponding pixel current magnitude of at least one other of the pixel regions of the array.

18. A method for using the light-emitting array of claim 17, the method comprising:
(A) selecting a first specified spatial distribution of pixel current magnitudes;
(B) operating the drive circuit to provide the first specified spatial distribution of pixel current magnitudes to the pixel regions of the array, causing the array to emit light according to a corresponding first spatial distribution of light emission intensity across the array;
(C) selecting a second specified spatial distribution of pixel current magnitudes that differs from the first specified spatial distribution of pixel current magnitudes; and
(D) operating the drive circuit to provide the second specified spatial distribution of pixel current magnitudes to the pixel regions of the array, causing the array to emit light according to a corresponding second spatial distribution of light emission intensity across the array that differs from the first spatial distribution of light emission intensity.

19. A method for making the light-emitting array of claim 17, the method comprising:
(A) forming the first and second semiconductor layers with the junction or active layer between them;
(B) forming the outcoupling structures on the second semiconductor layer;
(C) forming the first electrical contacts in electrical contact with the first semiconductor layer;
(D) forming the second electrical contacts in electrical contact with the second semiconductor layer;
(E) forming one or more electrical traces or interconnects connected to the sets of first and second electrical contacts; and
(F) connecting the drive circuit to the first and second electrical contacts using the electrical traces or interconnects.

20. A method for making the light-emitting array of claim 1, the method comprising:
(A) forming the first and second semiconductor layers with the junction or active layer between them;
(B) forming the outcoupling structures on the second semiconductor layer;
(C) forming the first electrical contacts in electrical contact with the first semiconductor layer; and
(D) forming the second electrical contacts in electrical contact with the second semiconductor layer.
